(19) United States
(12) Patent Application Publication
(10) Pub. No.: US 2015/0263140 A1
(43) Pub. Date: Sep. 17, 2015

(54) METHOD FOR MANUFACTURING SEMICONDUCTOR DEVICE

(71) Applicant: Semiconductor Energy Laboratory Co., LTD., Atsugi-shi (JP)

(72) Inventors: Shunpei YAMAZAKI, Tokyo (JP); Masayuki SAKAKURA, Isehara (JP); Takashi HAMADA, Atsugi (JP)

(21) Appl. No.: 14/645,123

(22) Filed: Mar. 11, 2015

(30) Foreign Application Priority Data
Mar. 14, 2014 (JP) 2014-051720

(51) Int. Cl. H01L 29/66; H01L 21/443; H01L 29/786; H01L 21/02; H01L 29/49

(52) U.S. Cl. CPC H01L 29/66969; H01L 21/0262; H01L 21/02614; H01L 29/4908; H01L 29/7869; H01L 21/02565; H01L 21/443

(57) ABSTRACT

Provided is a transistor with high field-effect mobility, a transistor having stable electrical characteristics, a transistor having a low off-state current, or a semiconductor device including the transistor. A method for manufacturing a semiconductor device including a first conductor, a first insulator over the first conductor, a first semiconductor over the first insulator, a second semiconductor over the first semiconductor, a second conductor and a third conductor over the second semiconductor, a third semiconductor over the second semiconductor, the second conductor, and the third conductor, a second insulator over the third semiconductor, and a fourth conductor over the second insulator. In the method, formation of layers is performed without exposure to the air.

### BACKGROUND OF THE INVENTION

1. Field of the Invention

The present invention relates to an object, a method, or a manufacturing method. Further, the present invention relates to a process, a machine, manufacture, or a composition of matter. In particular, the present invention relates to, for example, a semiconductor, a semiconductor device, a display device, a light-emitting device, a lighting device, a power storage device, a memory device, or a processor. Furthermore, the present invention relates to a method for manufacturing a semiconductor, a semiconductor device, a display device, a liquid crystal display device, a light-emitting device, or a memory device. Alternatively, the present invention relates to a driving method of a semiconductor device, a display device, a liquid crystal display device, a light-emitting device, or a memory device.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

2. Description of the Related Art

A technique for forming a transistor by using a semiconductor over a substrate having an insulating surface has attracted attention. The transistor is applied to a wide range of semiconductor devices such as an integrated circuit and a display device. Silicon is known as a semiconductor applicable to a transistor.

As silicon which is used as a semiconductor of a transistor, either amorphous silicon or polycrystalline silicon is used depending on the purpose. For example, in the case of a transistor included in a large display device, amorphous silicon, which can be formed using an established technique for forming a film over a large-sized substrate, is preferably used. On the other hand, in the case of a transistor included in a high-performance display device where a driver circuit and a pixel circuit are formed over the same substrate, it is preferable to use polycrystalline silicon, which can be used to form a transistor having a high field-effect mobility. As a method for forming polycrystalline silicon, high-temperature heat treatment or laser light treatment which is performed on amorphous silicon has been known.

In recent years, an oxide semiconductor has attracted attention. For example, a transistor which includes an amorphous In—Ga—Zn oxide is disclosed (see Patent Document 1). An oxide semiconductor can be formed by a sputtering method or the like, and thus can be used for a semiconductor of a transistor in a large-sized display device. Because a transistor including an oxide semiconductor has high field-effect mobility, a high-performance display device in which, for example, a driver circuit and a pixel circuit are formed over the same substrate can be obtained. In addition, there is an advantage that capital investment can be reduced because part of production equipment for a transistor including amorphous silicon can be retrofitted and utilized.

It is known that a transistor including an oxide semiconductor has an extremely low leakage current in an off state. For example, a CPU or the like with low-power consumption utilizing a characteristic of a low leakage current of the transistor including an oxide semiconductor is disclosed (see Patent Document 2). Patent Document 3 discloses that a transistor having high field-effect mobility can be obtained by a well potential formed using an active layer formed of an oxide semiconductor.

### REFERENCE

### Patent Document

[Patent Document 1] Japanese Published Patent Application No. 2006-165528
[Patent Document 2] Japanese Published Patent Application No. 2012-257187
[Patent Document 3] Japanese Published Patent Application No. 2012-59860

### SUMMARY OF THE INVENTION

An object is to provide a transistor having excellent electrical characteristics. Another object is to provide a transistor having stable electrical characteristics. Another object is to provide a transistor having a low off-state current. Another object is to provide a semiconductor device including the transistor. Another object is to provide a module that includes the semiconductor device. Another object is to provide an electronic device including the semiconductor device or the module. Another object is to provide a novel semiconductor device. Another object is to provide a novel module. Another object is to provide a novel electronic device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1)

One embodiment of the present invention is a method for manufacturing a semiconductor device, which includes a first step of forming a first conductor over a substrate by a CVD method; a second step of processing the first conductor after the first step to form a second conductor; a third step of forming a first insulator over the second conductor after the second step by a CVD method; a fourth step of forming a first semiconductor over the first insulator after the third step by a CVD method; a fifth step of forming a second semiconductor over the first semiconductor after the fourth step by a CVD method; a sixth step of processing the second semiconductor after the fifth step to form a third semiconductor; a seventh step of processing the first semiconductor after the sixth step to form a fourth semiconductor; an eighth step of forming a third conductor over the third semiconductor after the seventh step by a CVD method; a ninth step of processing the third conductor after the eighth step to form a fourth conductor and a fifth conductor and expose the third semiconductor; a tenth step of forming a fifth semiconductor over the third semiconductor, the fourth conductor, and the fifth conductor after the ninth step by a CVD method; an eleventh step of forming a second insulator over the fifth semiconductor after the tenth step by a CVD method; a twelfth step of forming a sixth conductor over the second insulator after the eleventh step by a CVD method; a thirteenth step of processing the sixth conductor after the twelfth step to form a seventh conductor; a fourteenth step of processing the second insulator after the thirteenth step to form a third insulator; and a fifteenth step of processing the fifth semiconductor after the fourteenth step to form a sixth semiconductor. Exposure to air does not occur between the third step and the fourth step. Exposure to air does not occur between the tenth step and the eleventh step.

(2)

One embodiment of the present invention is the method for manufacturing the semiconductor device of (1), in which exposure to air does not occur between the fourth step and the fifth step.

(3)

One embodiment of the present invention is the method for manufacturing the semiconductor device of (1) or (2), in which heat treatment is performed after the fifth step.

(4)

One embodiment of the present invention is the method for manufacturing the semiconductor device of any one of (1) to (3), which further includes, before the first step, a step of forming a fourth insulator with a function of blocking hydrogen by a CVD method.

(5)

One embodiment of the present invention is the method for manufacturing the semiconductor device of any one of (1) to (4), which further includes, after the fifteenth step, a step of forming a fifth insulator with a function of blocking hydrogen by a CVD method.

(6)

One embodiment of the present invention is the method for manufacturing the semiconductor device of any one of (1) to (5), which further includes, after the fourth step, a step of adding oxygen to the first semiconductor.

(7)

One embodiment of the present invention is a method for manufacturing a semiconductor device, which includes a first step of forming a first conductor over a substrate by a CVD method; a second step of processing the first conductor after the first step to form a second conductor; a third step of forming a first insulator over the second conductor after the second step by a CVD method; a fourth step of forming a first semiconductor over the first insulator after the third step by a CVD method; a fifth step of forming a second semiconductor over the first semiconductor after the fourth step by a CVD method; a sixth step of forming a third conductor over the second semiconductor after the fifth step by a CVD method; a seventh step of processing the third conductor after the sixth step to form a fourth conductor; an eighth step of processing the second semiconductor after the seventh step to form a third semiconductor; a ninth step of processing the first semiconductor after the eighth step to form a fourth semiconductor; a tenth step of processing the fourth conductor after the ninth step to form a fifth conductor and a sixth conductor and expose the third semiconductor; an eleventh step of forming a fifth semiconductor over the third semiconductor, the fifth conductor, and the sixth conductor after the tenth step by a CVD method; a twelfth step of forming a second insulator over the fifth semiconductor after the eleventh step by a CVD method; a thirteenth step of forming a seventh conductor over the second insulator after the twelfth step by a CVD method; a fourteenth step of processing the seventh conductor after the thirteenth step to form an eighth conductor; a fifteenth step of processing the second insulator after the fourteenth step to form a third insulator; and a sixteenth step of processing the fifth semiconductor after the fifteenth step to form a sixth semiconductor. Exposure to air does not occur between the third step and the fourth step. Exposure to air does not occur between the eleventh step and the twelfth step.

(8)

One embodiment of the present invention is the method for manufacturing the semiconductor device of (7), in which exposure to air does not occur between the fourth step and the fifth step.

(9)

One embodiment of the present invention is the method for manufacturing the semiconductor device of (7) or (8), in which exposure to air does not occur between the fifth step and the sixth step.

(10)

One embodiment of the present invention is the method for manufacturing the semiconductor device of any one of (7) to (9), in which heat treatment is performed after the fifth step.

(11)

One embodiment of the present invention is the method for manufacturing the semiconductor device of any one of (7) to (10), which further includes, before the first step, a step of forming a fourth insulator with a function of blocking hydrogen by a CVD method.

(12)

One embodiment of the present invention is the method for manufacturing the semiconductor device of any one of (7) to (11), which further includes, after the sixteenth step, a step of forming a fifth insulator with a function of blocking hydrogen by a CVD method.

(13)

One embodiment of the present invention is the method for manufacturing the semiconductor device of any one of (7) to (12), which further includes, after the fourth step, a step of adding oxygen to the first semiconductor.

It is possible to provide a transistor having excellent electrical characteristics. It is possible to provide a transistor having stable electrical characteristics. It is possible to provide a transistor having a low off-state current. It is possible to provide a semiconductor device including the transistor. It is possible to provide a module that includes the semiconductor device. It is possible to provide an electronic device including the semiconductor device or the module. It is possible to provide a novel semiconductor device. It is possible to provide a novel module. It is possible to provide a novel electronic device.

Note that the descriptions of these effects do not disturb the existence of other effects. In one embodiment of the present invention, there is no need to achieve all the effects. Other effects will be apparent from and can be derived from the description of the specification, the drawings, the claims, and the like.

### BRIEF DESCRIPTION OF THE DRAWINGS

FIGS. 1A and 1B are a top view and a cross-sectional view illustrating a transistor of one embodiment of the present invention.

FIGS. 2A to 2C are cross-sectional views illustrating a method for manufacturing a transistor of one embodiment of the present invention.

FIGS. 3A to 3C are cross-sectional views illustrating a method for manufacturing a transistor of one embodiment of the present invention.

FIGS. 4A, 4B1, 4B2, and 4C are cross-sectional views illustrating a method for manufacturing a transistor of one embodiment of the present invention.

FIG. 5 is a flow chart of a method for manufacturing a transistor of one embodiment of the present invention.

FIG. 6 is a flow chart of a method for manufacturing a transistor of one embodiment of the present invention.

FIG. 7 is a flow chart of a method for manufacturing a transistor of one embodiment of the present invention.

FIGS. 8A and 8B are a top view and a cross-sectional view illustrating a transistor of one embodiment of the present invention.

FIGS. 9A to 9C are cross-sectional views illustrating a method for manufacturing a transistor of one embodiment of the present invention.

FIGS. 10A to 10C are cross-sectional views illustrating a method for manufacturing a transistor of one embodiment of the present invention.

FIGS. 11A and 11B are cross-sectional views illustrating a method for manufacturing a transistor of one embodiment of the present invention.

FIG. 12 is a flow chart of a method for manufacturing a transistor of one embodiment of the present invention.

FIG. 13 is a flow chart of a method for manufacturing a transistor of one embodiment of the present invention.

FIG. 14 is a flow chart of a method for manufacturing a transistor of one embodiment of the present invention.

FIGS. 15A and 15B illustrate a manufacturing apparatus of one embodiment of the present invention.

FIGS. 16A and 16B are circuit diagrams of semiconductor devices of embodiments of the present invention.

FIGS. 17A and 17B are circuit diagrams of memory devices of embodiments of the present invention.

FIG. 18 is a block diagram of an RF tag of one embodiment of the present invention.

FIGS. 19A to 19F show application examples of an RF tag of one embodiment of the present invention.

FIG. 20 is a block diagram illustrating a CPU of one embodiment of the present invention.

FIG. 21 is a circuit diagram of a memory element of one embodiment of the present invention.

FIGS. 22A to 22C are a top view and circuit diagrams of a display device of one embodiment of the present invention.

FIG. 23 illustrates a display module of one embodiment of the present invention.

FIGS. 24A to 24F each illustrate an electronic device of one embodiment of the present invention.

FIGS. 25A1 to 25A3, FIGS. 25B1 and 25B2, and FIGS. 25C1 and 25C2 each illustrate an electronic device of one embodiment of the present invention.

FIGS. 26A and 26B each show a nanobeam electron diffraction pattern of an oxide semiconductor.

FIG. 27 is a graph showing relation between a cumulative electron dose and a size of a crystal part.

FIG. 28 illustrates a band structure of a semiconductor device of one embodiment of the present invention.

### DETAILED DESCRIPTION OF THE INVENTION

Hereinafter, embodiments of the present invention will be described in detail with the reference to the drawings. However, the present invention is not limited to the description below, and it is easily understood by those skilled in the art that modes and details disclosed herein can be modified in various ways. Further, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in drawings is sometimes exaggerated for clarity.

In this specification, for example, when the shape of an object is described with the use of a term such as “diameter”, “grain size (diameter)”, “dimension”, “size”, or “width”, the term can be regarded as the length of one side of a minimal cube where the object fits, or an equivalent circle diameter of a cross section of the object. The term “equivalent circle diameter of a cross section of the object” refers to the diameter of a perfect circle having the same area as the cross section of the object.

A voltage usually refers to a potential difference between a given potential and a reference potential (e.g., a ground potential (GND) or a source potential). A voltage can be referred to as a potential.

Note that the ordinal numbers such as “first” and “second” in this specification are used for convenience and do not denote the order of steps or the stacking order of layers. Therefore, for example, the term “first” can be replaced with the term “second”, “third”, or the like as appropriate. In addition, the ordinal numbers in this specification and the like are not necessarily the same as those which specify one embodiment of the present invention.

Note that a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Further, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. When the semiconductor is an oxide semiconductor, oxygen vacancies may be formed by entry of impurities such as hydrogen, for example. Further, when the semiconductor is silicon, examples of an impurity which changes the characteristics of the semiconductor include oxygen, Group 1 elements except hydrogen, Group 2 elements, Group 13 elements, and Group 15 elements.

In this specification, the phrase “A has a region with a concentration B” includes, for example, the cases where “the concentration in the entire region in a region of A in the depth direction is B”, “the average concentration in a region of A in the depth direction is B”, “the median value of the concentration in a region of A in the depth direction is B”, “the maximum value of the concentration in a region of A in the depth direction is B”, “the minimum value of the concentration in a region of A in the depth direction is B”, “a convergence value of the concentration in a region of A in the depth direction is B”, and “a concentration in a region of A in which a probable value is obtained in measurement is B”.

In this specification, the phrase “A has a region with a size B, a length B, a thickness B, a width B, or a distance B” includes, for example, “the size, the length, the thickness, the width, or the distance of the entire region in a region of A is B”, “the average value of the size, the length, the thickness, the width, or the distance of a region of A is B”, “the median value of the size, the length, the thickness, the width, or the distance of a region of A is B”, “the maximum value of the size, the length, the thickness, the width, or the distance of a region of A is B”, “the minimum value of the size, the length, the thickness, the width, or the distance of a region of A is B”, “a convergence value of the size, the length, the thickness, the width, or the distance of a region of A is B”, and “the size, the length, the thickness, the width, or the distance of a region of A in which a probable value is obtained in measurement is B”.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of the semiconductor in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A projects as compared with B” may indicate, for example, the case where at least one of end portions of A is positioned on an outer side than at least one of end portions of B in a top view or a cross-sectional view. Thus, the description “A projects as compared with B” can be alternatively referred to as the description “one of end portions of A is positioned on an outer side than one of end portions of B”.

Note that in this specification, the term “parallel” indicates that an angle formed between two straight lines ranges from −10° to 10°, and accordingly also includes the case where the angle ranges from −5° to 5°. The term “perpendicular” indicates that the angle formed between two straight lines is greater than or equal to 80° and less than or equal to 100°, and accordingly includes the case where the angle is greater than or equal to 85° and less than or equal to 95°.

In this specification, trigonal and rhombohedral crystal systems are included in a hexagonal crystal system.

### <Transistor Structure>

Transistor structures of embodiments of the present invention will be described below.

### <Transistor Structure 1>

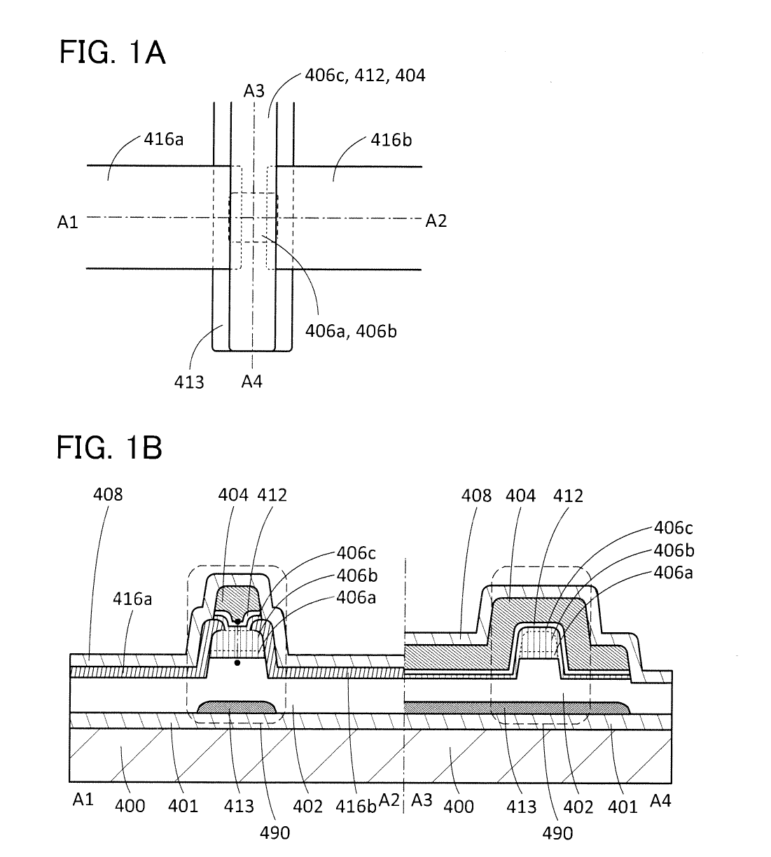

FIGS. 1A and 1B are a top view and a cross-sectional view of a transistor 490 of one embodiment of the present invention. FIG. 1A is a top view and FIG. 1B is a cross-sectional view taken along dashed-dotted line A1-A2 and dashed-dotted line A3-A4 in FIG. 1A. Note that for simplification of the drawing, some components are not illustrated in the top view in FIG. 1A.

The transistor 490 in FIGS. 1A and 1B includes a conductor 413 over a substrate 400, an insulator 402 having a projection over the substrate 400 and the conductor 413, a semiconductor 406a over the projection of the insulator 402, a semiconductor 406b over the semiconductor 406a, a conductor 416a and a conductor 416b which are in contact with a top surface and a side surface of the semiconductor 406b and which are arranged to be separated from each other, a semiconductor 406c over the semiconductor 406b, the conductor 416a, and the conductor 416b, an insulator 412 over the semiconductor 406c, a conductor 404 over the insulator 412, and an insulator 408 over the conductor 416a, the conductor 416b, and the conductor 404.

Note that the semiconductor 406c is in contact with at least a top surface and a side surface of the semiconductor 406b in the cross section taken along line A3-A4. Furthermore, the conductor 404 faces the top surface and the side surface of the semiconductor 406b with the semiconductor 406c and the insulator 412 provided therebetween in the cross section taken along line A3-A4. The conductor 413 faces a bottom surface of the semiconductor 406b with the insulator 402 provided therebetween. The insulator 402 does not necessarily include a projection. The insulator 401, the conductor 413, the semiconductor 406c, and the insulator 408 are not necessarily provided.

The semiconductor 406b serves as a channel formation region of the transistor 490. The conductor 404 serves as a first gate electrode (also referred to as a front gate electrode) of the transistor 490. The conductor 413 serves as a second gate electrode (also referred to as a back gate electrode) of the transistor 490. The conductor 416a and the conductor 416b serve as a source electrode and a drain electrode of the transistor 490. The insulator 408 functions as a barrier layer. The insulator 408 has, for example, a function of blocking oxygen and/or hydrogen. Alternatively, the insulator 408 has, for example, a higher capability of blocking oxygen and/or hydrogen than the semiconductor 406a and/or the semiconductor 406c.

The insulator 402 is preferably an insulator containing excess oxygen.

The insulator containing excess oxygen means an insulator from which oxygen is released by heat treatment, for example. The silicon oxide layer containing excess oxygen means a silicon oxide layer which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406a.

The insulator containing excess oxygen has a function of reducing oxygen vacancies in the semiconductor 406b in some cases. Such oxygen vacancies form DOS in the semiconductor 406b and serve as hole traps or the like. In addition, hydrogen comes into the site of such oxygen vacancies and forms electrons serving as carriers. Therefore, by reducing the oxygen vacancies in the semiconductor 406b, the transistor 490 can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in thermal desorption spectroscopy (TDS) analysis in the range of a surface temperature of 100° C. to 700° C. or 100° C. to 500° C.

Here, the method for measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is not taken into consideration either because the proportion of such a molecule in the natural world is minimal.

N_{O2}=N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value a is a coefficient affecting the ion intensity in the TDS analysis. Refer to Japanese Published Patent Application No. H6-275697 for details of the above formula. The amount of released oxygen is measured with, for example, a thermal desorption spectroscopy apparatus produced by ESCO Ltd., EMD-WA1000S/W using a silicon substrate containing hydrogen atoms at 1×10¹⁶ atoms/cm² as the reference sample.

Furthermore, in the TDS analysis, oxygen is partly detected as an oxygen atom. The ratio between oxygen molecules and oxygen atoms can be calculated from the ionization rate of the oxygen molecules. Note that since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

Note that the above description of the insulator containing excess oxygen applies to the semiconductor containing excess oxygen in some cases.

As illustrated in FIG. 1B, the side surfaces of the semiconductor 406b are in contact with the conductor 416a and the conductor 416b. The semiconductor 406b can be electrically surrounded by an electric field of the conductor 404 (a structure in which a semiconductor is electrically surrounded by an electric field of a conductor is referred to as a surrounded channel (s-channel) structure). Therefore, a channel is formed in the entire semiconductor 406b (bulk) in some cases. In the s-channel structure, a large amount of current can flow between a source and a drain of a transistor, so that a high on-state current can be obtained.

The s-channel structure is suitable for a miniaturized transistor because a high on-state current can be obtained. A semiconductor device including the miniaturized transistor can have a high integration degree and high density. For example, the channel length of the transistor 490 is preferably less than or equal to 40 nm, more preferably less than or equal to 30 nm, still more preferably less than or equal to 20 nm and the channel width of the transistor 490 is preferably less than or equal to 40 nm, more preferably less than or equal to 30 nm, still more preferably less than or equal to 20 nm.

Furthermore, by applying a lower voltage or a higher voltage than a source electrode to the conductor 413, the threshold voltage of the transistor 490 may be shifted in the positive direction or the negative direction. For example, when the threshold voltage of the transistor 490 is shifted in the positive direction, the normally-off transistor 490 which is in a non-conduction state (off state) even when the gate voltage is 0 V can be obtained in some cases. The voltage applied to the conductor 413 may be a variable or a fixed voltage. When the voltage applied to the conductor 413 is a variable, a circuit for controlling the voltage may be electrically connected to the conductor 413.

A structure of an oxide semiconductor which can be used as the semiconductor 406a, the semiconductor 406b, the semiconductor 406c, or the like is described below.

A structure of an oxide semiconductor is described below.

An oxide semiconductor is classified roughly into a single-crystal oxide semiconductor and a non-single-crystal oxide semiconductor. The non-single-crystal oxide semiconductor includes any of a c-axis aligned crystalline oxide semiconductor (CAAC-OS), a polycrystalline oxide semiconductor, a microcrystalline oxide semiconductor, an amorphous oxide semiconductor, and the like.

First, a CAAC-OS is described.

The CAAC-OS is one of oxide semiconductors having a plurality of c-axis aligned crystal parts.

When a combined analysis image (also referred to as a high-resolution TEM image) of a bright-field image and a diffraction pattern of the CAAC-OS is observed by a transmission electron microscope (TEM), a plurality of crystal parts are seen. However, in the high-resolution TEM image, a boundary between crystal parts, that is, a grain boundary is not clearly observed. Thus, in the CAAC-OS, a reduction in electron mobility due to the grain boundary is less likely to occur.

In the high-resolution cross-sectional TEM image of the CAAC-OS observed in a direction substantially parallel to the sample surface, metal atoms arranged in a layered manner are seen in the crystal parts. Each metal atom layer reflects unevenness of a surface over which the CAAC-OS is formed (hereinafter, a surface over which the CAAC-OS is formed is referred to as a formation surface) or a top surface of the CAAC-OS, and is arranged parallel to the formation surface or the top surface of the CAAC-OS.

In the high-resolution plan-view TEM image of the CAAC-OS observed in a direction substantially perpendicular to the sample surface, metal atoms arranged in a triangular or hexagonal configuration are seen in the crystal parts. However, there is no regularity of arrangement of metal atoms between different crystal parts.

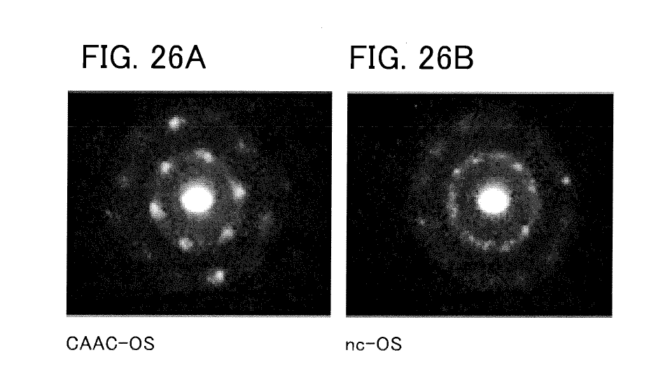

Note that in an electron diffraction pattern of the CAAC-OS, spots (bright spots) having alignment are shown. For example, when electron diffraction with an electron beam having a diameter of 1 nm or more and 30 nm or less (such electron diffraction is also referred to as nanobeam electron diffraction) is performed on the top surface of the CAAC-OS, spots are observed (see FIG. 26A).

The high-resolution cross-sectional TEM image and the high-resolution plan-view TEM image show that the crystal parts in the CAAC-OS have alignment.

Most of the crystal parts included in the CAAC-OS each fit inside a cube whose one side is less than 100 nm. Thus, there is a case where a crystal part included in the CAAC-OS fits inside a cube whose one side is less than 10 nm, less than 5 nm, or less than 3 nm. Note that when a plurality of crystal parts included in the CAAC-OS are connected to each other, one large crystal region is formed in some cases. For example, a crystal region with an area of larger than or equal to 2500 nm², larger than or equal to 5 μm², or larger than or equal to 1000 μm² is observed in some cases in the high-resolution plan-view TEM image.

A CAAC-OS is subjected to structural analysis with an X-ray diffraction (XRD) apparatus. For example, when the CAAC-OS including an InGaZnO₄ crystal is analyzed by an out-of-plane method, a peak appears frequently when the diffraction angle (2θ) is around 31°. This peak is derived from the (0 0 9) plane of the InGaZnO₄ crystal, which indicates that crystals in the CAAC-OS have c-axis alignment, and that the c-axes are aligned in a direction substantially perpendicular to the formation surface or the top surface of the CAAC-OS.

On the other hand, when the CAAC-OS is analyzed by an in-plane method in which an X-ray enters a sample in a direction substantially perpendicular to the c-axis, a peak appears frequently when 2θ is around 56°. This peak is derived from the (1 1 0) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor of InGaZnO₄, six peaks appear. The six peaks are derived from crystal planes equivalent to the (1 1 0) plane. On the other hand, in the case of a CAAC-OS, a peak is not clearly observed even when φ scan is performed with 2θ fixed at around 56°.

According to the above results, in the CAAC-OS having c-axis alignment, while the directions of a-axes and b-axes are irregularly oriented between crystal parts, the c-axes are aligned in a direction parallel to a normal vector of a formation surface or a normal vector of a top surface. Thus, each metal atom layer arranged in a layered manner observed in the high-resolution cross-sectional TEM image corresponds to a plane parallel to the a-b plane of the crystal.

Note that the crystal part is formed concurrently with deposition of the CAAC-OS or is formed through crystallization treatment such as heat treatment. As described above, the c-axis of the crystal is aligned in a direction parallel to a normal vector of a formation surface or a normal vector of a top surface of the CAAC-OS. Thus, for example, in the case where a shape of the CAAC-OS is changed by etching or the like, the c-axis might not be necessarily parallel to a normal vector of a formation surface or a normal vector of a top surface of the CAAC-OS.

In addition, distribution of c-axis aligned crystal parts in the CAAC-OS is not necessarily uniform. For example, in the case where crystal growth leading to the crystal parts of the CAAC-OS occurs from the vicinity of the top surface of the CAAC-OS, the proportion of the c-axis aligned crystal parts in the vicinity of the top surface is higher than that in the vicinity of the formation surface in some cases. Furthermore, when an impurity is added to the CAAC-OS, a region to which the impurity is added is altered, and the proportion of the c-axis aligned crystal parts in the CAAC-OS varies depending on a region, in some cases.

Note that when the CAAC-OS with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS. It is preferable that in the CAAC-OS, a peak of 2θ appear at around 31° and a peak of 2θ not appear at around 36°.

The CAAC-OS is an oxide semiconductor having low impurity concentration. The impurity is an element other than the main components of the oxide semiconductor, such as hydrogen, carbon, silicon, or a transition metal element. In particular, an element that has higher bonding strength to oxygen than a metal element included in the oxide semiconductor, such as silicon, disturbs the atomic arrangement of the oxide semiconductor by depriving the oxide semiconductor of oxygen and causes a decrease in crystallinity. A heavy metal such as iron or nickel, argon, carbon dioxide, or the like has a large atomic radius (or molecular radius), and thus disturbs the atomic arrangement of the oxide semiconductor and decreases crystallinity when it is contained in the oxide semiconductor. Note that the impurity contained in the oxide semiconductor might serve as a carrier trap or a carrier generation source.

The CAAC-OS is an oxide semiconductor having a low density of defect states. In some cases, oxygen vacancies in the oxide semiconductor serve as carrier traps or serve as carrier generation sources when hydrogen is captured therein.

The state in which impurity concentration is low and density of defect states is low (the number of oxygen vacancies is small) is referred to as a “highly purified intrinsic” or “substantially highly purified intrinsic” state. A highly purified intrinsic or substantially highly purified intrinsic oxide semiconductor has few carrier generation sources, and thus can have a low carrier density. Thus, a transistor including the oxide semiconductor rarely has negative threshold voltage (is rarely normally on). The highly purified intrinsic or substantially highly purified intrinsic oxide semiconductor has few carrier traps. Accordingly, the transistor including the oxide semiconductor has small changes in electrical characteristics and high reliability. Electric charge captured by the carrier traps in the oxide semiconductor takes a long time to be released, and might behave like fixed electric charge. Thus, the transistor that includes the oxide semiconductor having high impurity concentration and a high density of defect states has unstable electrical characteristics in some cases.

In a transistor using the CAAC-OS, changes in electrical characteristics due to irradiation with visible light or ultraviolet light are small.

Next, a polycrystalline oxide semiconductor is described.

In a high-resolution TEM image of the polycrystalline oxide semiconductor, crystal grains are observed. In most cases, the crystal grain size in the polycrystalline oxide semiconductor is greater than or equal to 2 nm and less than or equal to 300 nm, greater than or equal to 3 nm and less than or equal to 100 nm, or greater than or equal to 5 nm and less than or equal to 50 nm in the high-resolution TEM image, for example. Moreover, in the high-resolution TEM image of the polycrystalline oxide semiconductor, a boundary between crystals may be observed.

The polycrystalline oxide semiconductor may include a plurality of crystal grains, and alignment of crystals may be different in the plurality of crystal grains. A polycrystalline oxide semiconductor is subjected to structural analysis with an XRD apparatus. For example, when the polycrystalline oxide semiconductor including an InGaZnO₄ crystal is analyzed by an out-of-plane method, peaks of 20 appear at around 31°, 36°, and the like in some cases.

The polycrystalline oxide semiconductor has high crystallinity and thus has high electron mobility in some cases. Accordingly, a transistor including the polycrystalline oxide semiconductor has high field-effect mobility. Note that there are cases in which an impurity is segregated at the grain boundary between the crystals in the polycrystalline oxide semiconductor. Moreover, the grain boundary of the polycrystalline oxide semiconductor becomes a defect state. Since the grain boundary of the polycrystalline oxide semiconductor may serve as a carrier trap or a carrier generation source, a transistor including the polycrystalline oxide semiconductor has larger changes in electrical characteristics and lower reliability than a transistor including a CAAC-OS in some cases.

Next, a microcrystalline oxide semiconductor is described.

A microcrystalline oxide semiconductor has a region where a crystal part is observed in a high-resolution TEM image and a region where a crystal part is not clearly observed in a high-resolution TEM image. In most cases, a crystal part in the microcrystalline oxide semiconductor is greater than or equal to 1 nm and less than or equal to 100 nm, or greater than or equal to 1 nm and less than or equal to 10 nm. A microcrystal with a size greater than or equal to 1 nm and less than or equal to 10 nm, or a size greater than or equal to 1 nm and less than or equal to 3 nm is specifically referred to as nanocrystal (nc). An oxide semiconductor including nanocrystal is referred to as an nc-OS (nanocrystalline oxide semiconductor). In a high-resolution TEM image of the nc-OS, for example, a grain boundary is not clearly observed in some cases.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic order. Note that there is no regularity of crystal orientation between different crystal parts in the nc-OS. Thus, the orientation of the whole film is not observed. Accordingly, in some cases, the nc-OS cannot be distinguished from an amorphous oxide semiconductor depending on an analysis method. For example, when the nc-OS is subjected to structural analysis by an out-of-plane method with an XRD apparatus using an X-ray having a diameter larger than that of a crystal part, a peak showing a crystal plane does not appear. A diffraction pattern like a halo pattern appears in a selected-area electron diffraction pattern of the nc-OS obtained by using an electron beam having a probe diameter (e.g., larger than or equal to 50 nm) larger than the diameter of a crystal part. Meanwhile, spots are shown in a nanobeam electron diffraction pattern of the nc-OS obtained by using an electron beam having a probe diameter close to, or smaller than the diameter of a crystal part. In a nanobeam electron diffraction pattern of the nc-OS, regions with high luminance in a circular (ring) pattern are shown in some cases. Also in a nanobeam electron diffraction pattern of the nc-OS, a plurality of spots are shown in a ring-like region in some cases (see FIG. 26B).

The nc-OS is an oxide semiconductor that has high regularity as compared to an amorphous oxide semiconductor. Thus, the nc-OS has a lower density of defect states than an amorphous oxide semiconductor. Note that there is no regularity of crystal orientation between different crystal parts in the nc-OS. Hence, the nc-OS has a higher density of defect states than the CAAC-OS.

Thus, the nc-OS may have a higher carrier density than the CAAC-OS. The oxide semiconductor having a high carrier density may have high electron mobility. Thus, a transistor including the nc-OS may have high field-effect mobility. The nc-OS has a higher defect state density than the CAAC-OS, and thus may have a lot of carrier traps. Consequently, a transistor including the nc-OS has larger changes in electrical characteristics and lower reliability than a transistor including the CAAC-OS. The nc-OS can be formed easily as compared to the CAAC-OS because nc-OS can be formed even when a relatively large amount of impurities are included; thus, depending on the purpose, the nc-OS can be favorably used in some cases. Thus, a semiconductor device including the transistor including the nc-OS can be manufactured with high productivity in some cases.

Next, an amorphous oxide semiconductor is described.

The amorphous oxide semiconductor has disordered atomic arrangement and no crystal part. For example, the amorphous oxide semiconductor does not have a specific state as in quartz.

In the high-resolution TEM image of the amorphous oxide semiconductor, crystal parts cannot be found.

When the amorphous oxide semiconductor is subjected to structural analysis by an out-of-plane method with an XRD apparatus, a peak showing a crystal plane does not appear. A halo pattern is shown in an electron diffraction pattern of the amorphous oxide semiconductor. Furthermore, a halo pattern is shown but a spot is not shown in a nanobeam electron diffraction pattern of the amorphous oxide semiconductor.

The amorphous oxide semiconductor contains impurities such as hydrogen at a high concentration. In addition, the amorphous oxide semiconductor has a high density of defect states.

The oxide semiconductor having a high impurity concentration and a high density of defect states has many carrier traps or many carrier generation sources.

Thus, the amorphous oxide semiconductor has a much higher carrier density than the nc-OS in some cases. Therefore, a transistor including the amorphous oxide semiconductor tends to be normally on. Therefore, in some cases, such an amorphous oxide semiconductor can be applied to a transistor that needs to be normally on. Since the amorphous oxide semiconductor has a high density of defect states, carrier traps might be increased. Consequently, a transistor including the amorphous oxide semiconductor has larger changes in electrical characteristics and lower reliability than a transistor including the CAAC-OS or the nc-OS.

Next, a single-crystal oxide semiconductor is described.

The single-crystal oxide semiconductor has a lower impurity concentration and a lower density of defect states (few oxygen vacancies). Thus, the carrier density can be decreased. Thus, a transistor including the single-crystal oxide semiconductor is unlikely to be normally on. Moreover, since the single-crystal oxide semiconductor has a lower impurity concentration and a lower density of defect states, carrier traps might be reduced. Thus, the transistor including the single-crystal oxide semiconductor has small changes in electrical characteristics and accordingly has high reliability.

Note that when the oxide semiconductor has few defects, the density thereof is increased. When the oxide semiconductor has high crystallinity, the density thereof is increased. When the oxide semiconductor has a lower concentration of impurities such as hydrogen, the density thereof is increased. The single-crystal oxide semiconductor has a higher density than the CAAC-OS. The CAAC-OS has a higher density than the microcrystalline oxide semiconductor. The polycrystalline oxide semiconductor has a higher density than the microcrystalline oxide semiconductor. The microcrystalline oxide semiconductor has a higher density than the amorphous oxide semiconductor.

Note that an oxide semiconductor may have a structure having physical properties between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be seen.

Furthermore, in the high-resolution TEM image, there are a region where a crystal part is clearly observed and a region where a crystal part is not observed. In the a-like OS, crystallization by a slight amount of electron beam used for TEM observation occurs and growth of the crystal part is found sometimes. By contrast, crystallization by a slight amount of electron beam used for TEM observation is less observed in the nc-OS having good quality.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Thus, the distance between the adjacent layers is equivalent to the lattice spacing on the (0 0 9) plane (also referred to as d value). The value is calculated to be 0.29 nm from crystal structural analysis. Thus, each of the lattice fringes having a distance therebetween of from 0.28 nm to 0.30 nm is regarded as corresponding to the a-b plane of the InGaZnO₄ crystal, focusing on the lattice fringes in the high-resolution TEM image. The maximum length of the region in which the lattice fringes are observed is regarded as the size of the crystal parts of the a-like OS and the nc-OS. Note that the crystal part whose size is 0.8 nm or larger is selectively evaluated.

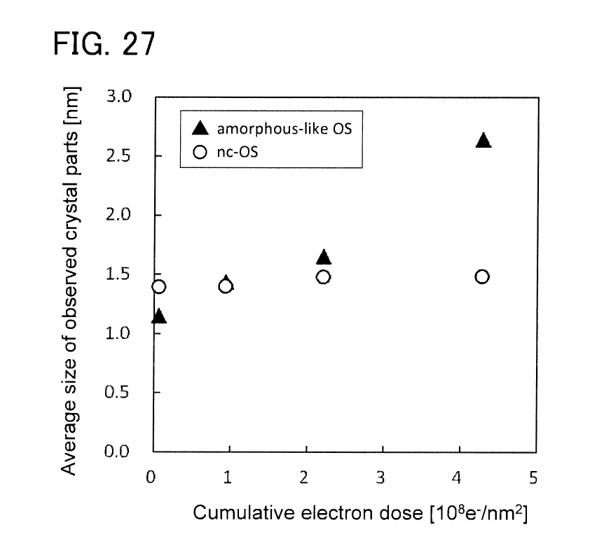

Change in average size of crystal parts (20-40 points) in the a-like OS and the nc-OS is examined using the high-resolution TEM images. FIG. 27 shows relation between a cumulative electron dose and the crystal part size. As in FIG. 27, the crystal part size in the a-like OS increases with an increase of the cumulative electron dose. Specifically, the crystal part of approximately 1.2 nm at the start of TEM observation grows to a size of approximately 2.6 nm at the cumulative electron dose of 4.2×10⁸ e⁻/nm². By contrast, the crystal part size in the good-quality nc-OS shows little change from the start of electron irradiation to the cumulative electron dose of 4.2×10⁸ e⁻/nm² regardless of the cumulative electron dose.

Furthermore, in FIG. 27, by linear approximation of the change in the crystal part size in the a-like OS and the nc-OS and extrapolation to the cumulative electron dose of 0 e⁻/nm², the average size of the crystal part is found to be a positive value. This means that the crystal parts exist in the a-like OS and the nc-OS before TEM observation.

Note that an oxide semiconductor may be a stacked layer including two or more films of an amorphous oxide semiconductor, a microcrystalline oxide semiconductor, and a CAAC-OS, for example.

The above oxide semiconductor can be used as the semiconductor 406a, the semiconductor 406b, the semiconductor 406c, or the like.

Next, the other components of a semiconductor which can be used as the semiconductor 406a, the semiconductor 406b, the semiconductor 406c, or the like are described.

The semiconductor 406b is an oxide semiconductor containing indium, for example. An oxide semiconductor can have high carrier mobility (electron mobility) by containing indium, for example. The semiconductor 406b preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having high bonding energy with oxygen, for example. The element M is an element whose bonding energy with oxygen is higher than that of indium, for example. The element M is an element that can increase the energy gap of the oxide semiconductor, for example. Furthermore, the semiconductor 406b preferably contains zinc. When the oxide semiconductor contains zinc, the oxide semiconductor is easily to be crystallized, for example.

Note that the semiconductor 406b is not limited to the oxide semiconductor containing indium. The semiconductor 406b may be, for example, an oxide semiconductor which does not contain indium and contains zinc, an oxide semiconductor which does not contain indium and contains gallium, or an oxide semiconductor which does not contain indium and contains tin, e.g., a zinc tin oxide, a gallium tin oxide, or gallium oxide.

For the semiconductor 406b, an oxide with a wide energy gap may be used. For example, the energy gap of the semiconductor 406b is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

For example, the semiconductor 406a and the semiconductor 406c are oxide semiconductors including one or more elements other than oxygen included in the semiconductor 406b. Since the semiconductor 406a and the semiconductor 406c each include one or more elements other than oxygen included in the semiconductor 406b, an interface state is less likely to be formed at the interface between the semiconductor 406a and the semiconductor 406b and the interface between the semiconductor 406b and the semiconductor 406c.

The case where the semiconductor 406a, the semiconductor 406b, and the semiconductor 406c contain indium is described. In the case of using an In-M-Zn oxide as the semiconductor 406a, when a summation of In and M is assumed to be 100 atomic %, the proportions of In and M are preferably set to be less than 50 atomic % and greater than or equal to 50 atomic %, respectively, more preferably less than 25 atomic % and greater than or equal to 75 atomic %, respectively. In the case of using an In-M-Zn oxide as the semiconductor 406b, when a summation of In and M is assumed to be 100 atomic %, the proportions of In and M are preferably set to be greater than or equal to 25 atomic % and less than 75 atomic %, respectively, more preferably greater than or equal to 34 atomic % and less than 66 atomic %, respectively. In the case of using an In-M-Zn oxide as the semiconductor 406c, when a summation of In and M is assumed to be 100 atomic %, the proportions of In and M are preferably set to be less than 50 atomic % and greater than or equal to 50 atomic %, respectively, more preferably less than 25 atomic % and greater than or equal to 75 atomic %, respectively. Note that the semiconductor 406c may be an oxide that is a type the same as that of the semiconductor 406a.

As the semiconductor 406b, an oxide having an electron affinity higher than those of the semiconductors 406a and 406c is used. For example, as the semiconductor 406b, an oxide having an electron affinity higher than those of the semiconductors 406a and 406c by 0.07 eV or higher and 1.3 eV or lower, preferably 0.1 eV or higher and 0.7 eV or lower, more preferably 0.15 eV or higher and 0.4 eV or lower is used. Note that the electron affinity refers to an energy difference between the vacuum level and the bottom of the conduction band.

An indium gallium oxide has a small electron affinity and a high oxygen-blocking property. Therefore, the semiconductor 406c preferably includes an indium gallium oxide. The gallium atomic ratio [Ga/(In+Ga)] is, for example, higher than or equal to 70%, preferably higher than or equal to 80%, more preferably higher than or equal to 90%.

Note that the semiconductor 406a and/or the semiconductor 406c may be gallium oxide. For example, when gallium oxide is used as the semiconductor 406a, a leakage current between the conductor 413 and the conductor 416a or the conductor 416b can be reduced. For example, when gallium oxide is used as the semiconductor 406c, a leakage current between the conductor 404 and the conductor 416a or the conductor 416b can be reduced. In other words, the off-state current of the transistor 490 can be reduced.

At this time, when a gate voltage is applied, a channel is formed in the semiconductor 406b having the highest electron affinity in the semiconductor 406a, the semiconductor 406b, and the semiconductor 406c.

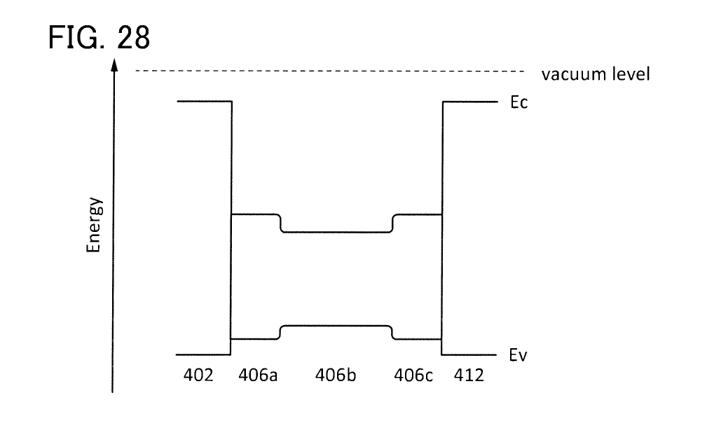

FIG. 28 shows a band structure which corresponds to a cross section taken along a dashed-dotted line in FIG. 1B. FIG. 28 shows a vacuum level (denoted by vacuum level), and an energy of the bottom of the conduction band (denoted by Ec) and an energy of the top of the valence band (denoted by Ev) of each of the layers.

Here, in some cases, there is a mixed region of the semiconductor 406a and the semiconductor 406b between the semiconductor 406a and the semiconductor 406b. Furthermore, in some cases, there is a mixed region of the semiconductor 406b and the semiconductor 406c between the semiconductor 406b and the semiconductor 406c. The mixed region has a low interface state density. For that reason, the stack including the semiconductor 406a, the semiconductor 406b, and the semiconductor 406c has a band structure where energy at each interface and in the vicinity of the interface is changed continuously (continuous junction).

At this time, electrons move mainly in the semiconductor 406b, not in the semiconductor 406a and the semiconductor 406c. Thus, when the interface state density at the interface between the semiconductor 406a and the semiconductor 406b and the interface state density at the interface between the semiconductor 406b and the semiconductor 406c are decreased, electron movement in the semiconductor 406b is less likely to be inhibited and the on-state current of the transistor 490 can be increased.

In the case where the transistor 490 has an s-channel structure, a channel is formed in the whole of the semiconductor 406b. Therefore, as the semiconductor 406b has a larger thickness, a channel region becomes larger. In other words, the thicker the semiconductor 406b is, the larger the on-state current of the transistor 490 is. For example, the semiconductor 406b has a region with a thickness of greater than or equal to 20 nm, preferably greater than or equal to 40 nm, more preferably greater than or equal to 60 nm, still more preferably greater than or equal to 100 nm. Note that the semiconductor 406b has a region with a thickness of, for example, less than or equal to 300 nm, preferably less than or equal to 200 nm, more preferably less than or equal to 150 nm because the productivity of the semiconductor device might be decreased.

Moreover, the thickness of the semiconductor 406c is preferably as small as possible to increase the on-state current of the transistor 490. The semiconductor 406c has a region with a thickness of less than 10 nm, preferably less than or equal to 5 nm, more preferably less than or equal to 3 nm, for example. Meanwhile, the semiconductor 406c has a function of blocking entry of elements other than oxygen (such as hydrogen and silicon) included in the adjacent insulator into the semiconductor 406b where a channel is formed. For this reason, it is preferable that the semiconductor 406c have a certain thickness. The semiconductor 406c has a region with a thickness of greater than or equal to 0.3 nm, preferably greater than or equal to 1 nm, more preferably greater than or equal to 2 nm, for example. The semiconductor 406c preferably has an oxygen blocking property to suppress outward diffusion of oxygen released from the insulator 402 and the like.

To improve reliability, preferably, the thickness of the semiconductor 406a is large and the thickness of the semiconductor 406c is small. For example, the semiconductor 406a has a region with a thickness of greater than or equal to 10 nm, preferably greater than or equal to 20 nm, more preferably greater than or equal to 40 nm, still more preferably greater than or equal to 60 nm. When the thickness of the semiconductor 406a is made large, a distance from an interface between the adjacent insulator and the semiconductor 406a to the semiconductor 406b in which a channel is formed can be large. Since the productivity of the semiconductor device might be decreased, the semiconductor 406a has a region with a thickness of, for example, less than or equal to 200 nm, preferably less than or equal to 120 nm, more preferably less than or equal to 80 nm.

For example, silicon in the oxide semiconductor might serve as a carrier trap or a carrier generation source. Therefore, the silicon concentration of the semiconductor 406b is preferably as low as possible. For example, a region with a silicon concentration of lower than 1×10¹⁹ atoms/cm³, preferably lower than 5×10¹⁸ atoms/cm³, more preferably lower than 2×10¹⁸ atoms/cm³ which is measured by secondary ion mass spectrometry (SIMS) is provided between the semiconductor 406b and the semiconductor 406a. A region with a silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the semiconductor 406b and the semiconductor 406c.

The semiconductor 406b has a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. It is preferable to reduce the concentration of hydrogen in the semiconductor 406a and the semiconductor 406c in order to reduce the concentration of hydrogen in the semiconductor 406b. The semiconductor 406a and the semiconductor 406c each have a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. The semiconductor 406b has a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³. It is preferable to reduce the concentration of nitrogen in the semiconductor 406a and the semiconductor 406c in order to reduce the concentration of nitrogen in the semiconductor 406b. The semiconductor 406a and the semiconductor 406c each have a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

Note that when copper enters the oxide semiconductor, an electron trap might be generated. The electron trap might shift the threshold voltage of the transistor in the positive direction. Therefore, the concentration of copper on the surface of or in the semiconductor 406b is preferably as low as possible. For example, the semiconductor 406b preferably has a region in which the concentration of copper is lower than or equal to 1×10¹⁹ atoms/cm³, lower than or equal to 5×10¹⁸ atoms/cm³, or lower than or equal to 1×10¹⁸ atoms/cm³.

The above three-layer structure is an example. For example, a two-layer structure without the semiconductor 406a or the semiconductor 406c may be employed. A four-layer structure in which any one of the semiconductors described as examples of the semiconductor 406a, the semiconductor 406b, and the semiconductor 406c is provided under or over the semiconductor 406a or under or over the semiconductor 406c may be employed. An n-layer structure (n is an integer of 5 or more) in which any one of the semiconductors described as examples of the semiconductor 406a, the semiconductor 406b, and the semiconductor 406c is provided at two or more of the following positions: over the semiconductor 406a, under the semiconductor 406a, over the semiconductor 406c, and under the semiconductor 406c.

Alternatively, at least part (or all) of the conductor 416a (and/or the conductor 416b) is in contact with at least part (or all) of a surface, a side surface, a top surface, and/or a bottom surface of a semiconductor, e.g., the semiconductor 406b. Alternatively, at least part (or all) of the conductor 416a (and/or the conductor 416b) is in contact with at least part (or all) of a semiconductor, e.g., the semiconductor 406b.

As the substrate 400, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The substrate 400 has a region with a thickness of, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 400 has a small thickness, the weight of the semiconductor device can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, metal, an alloy, resin, glass, or fiber thereof can be used, for example. The flexible substrate 400 preferably has a lower coefficient of linear expansion because deformation due to an environment is suppressed. The flexible substrate 400 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate 400 because of its low coefficient of linear expansion.

The insulator 401 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 401 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide. Note that the insulator 401 preferably contains aluminum oxide. For example, when the insulator 401 contains aluminum oxide, entry of impurities such as hydrogen into the semiconductor 406b can be inhibited.

The conductor 413 may be formed to have a single-layer structure or a stacked-layer structure using a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten, for example. Alternatively, an alloy or a compound containing the above element may be used: a conductor containing aluminum, a conductor containing copper and titanium, a conductor containing copper and manganese, a conductor containing indium, tin, and oxygen, a conductor containing titanium and nitrogen, or the like may be used.

The insulator 402 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that the insulator 402 preferably contains an insulator with a high dielectric constant. For example, the insulator 402 preferably contains gallium oxide, hafnium oxide, an oxide containing aluminum and hafnium, an oxynitride containing aluminum and hafnium, an oxide containing silicon and hafnium, or an oxynitride containing silicon and hafnium. The insulator 402 preferably has a stacked-layer structure including silicon oxide or silicon oxynitride and an insulator with a high dielectric constant. Because silicon oxide and silicon oxynitride have thermal stability, combination of silicon oxide or silicon oxynitride with an insulator with a high dielectric constant allows the stacked-layer structure to be thermally stable and have a high dielectric constant. When aluminum oxide, gallium oxide, or hafnium oxide is contained on the semiconductor 406a side, for example, silicon contained in silicon oxide or silicon oxynitride can be prevented from entering the semiconductor 406a and/or the semiconductor 406b. When silicon oxide or silicon oxynitride is contained on the semiconductor 406a side, for example, trap centers might be formed at the interface between aluminum oxide, gallium oxide, or hafnium oxide and silicon oxide or silicon oxynitride. The trap centers can shift the threshold voltage of the transistor in the positive direction by trapping electrons in some cases. Note that the dielectric constant of the insulator with a high dielectric constant is greater than or equal to 6, preferably greater than or equal to 8, further preferably greater than or equal to 12, still further preferably greater than or equal to 20.

The insulator 402 may have a function of preventing diffusion of impurities from the substrate 400. In the case where the semiconductor 406b is an oxide semiconductor, the insulator 402 can have a function of supplying oxygen to the semiconductor 406b.

Each of the conductor 416a and the conductor 416b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. Alternatively, an alloy or a compound containing the above element may be used: a conductor containing aluminum, a conductor containing copper and titanium, a conductor containing copper and manganese, a conductor containing indium, tin, and oxygen, a conductor containing titanium and nitrogen, or the like may be used.

The insulator 412 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 412 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that the insulator 412 preferably contains an insulator with a high dielectric constant. For example, the insulator 412 preferably contains gallium oxide, hafnium oxide, an oxide containing aluminum and hafnium, an oxynitride containing aluminum and hafnium, an oxide containing silicon and hafnium, or an oxynitride containing silicon and hafnium. The insulator 412 preferably has a stacked-layer structure including silicon oxide or silicon oxynitride and an insulator with a high dielectric constant. Because silicon oxide and silicon oxynitride have thermal stability, combination of silicon oxide or silicon oxynitride with an insulator with a high dielectric constant allows the stacked-layer structure to be thermally stable and have a high dielectric constant. When aluminum oxide, gallium oxide, or hafnium oxide is contained on the semiconductor 406c side, for example, silicon contained in silicon oxide or silicon oxynitride can be prevented from entering the semiconductor 406c and/or the semiconductor 406b. When silicon oxide or silicon oxynitride is contained on the semiconductor 406c side, for example, trap centers might be formed at the interface between aluminum oxide, gallium oxide, or hafnium oxide and silicon oxide or silicon oxynitride. The trap centers can shift the threshold voltage of the transistor in the positive direction by trapping electrons in some cases.

The conductor 404 may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. Alternatively, an alloy or a compound containing the above element may be used: a conductor containing aluminum, a conductor containing copper and titanium, a conductor containing copper and manganese, a conductor containing indium, tin, and oxygen, a conductor containing titanium and nitrogen, or the like may be used.

The insulator 408 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 408 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide. Note that the insulator 408 preferably contains aluminum oxide. For example, when the insulator 408 contains aluminum oxide, entry of impurities such as hydrogen into the semiconductor 406b can be inhibited.

### <Method for Manufacturing Transistor Structure 1>

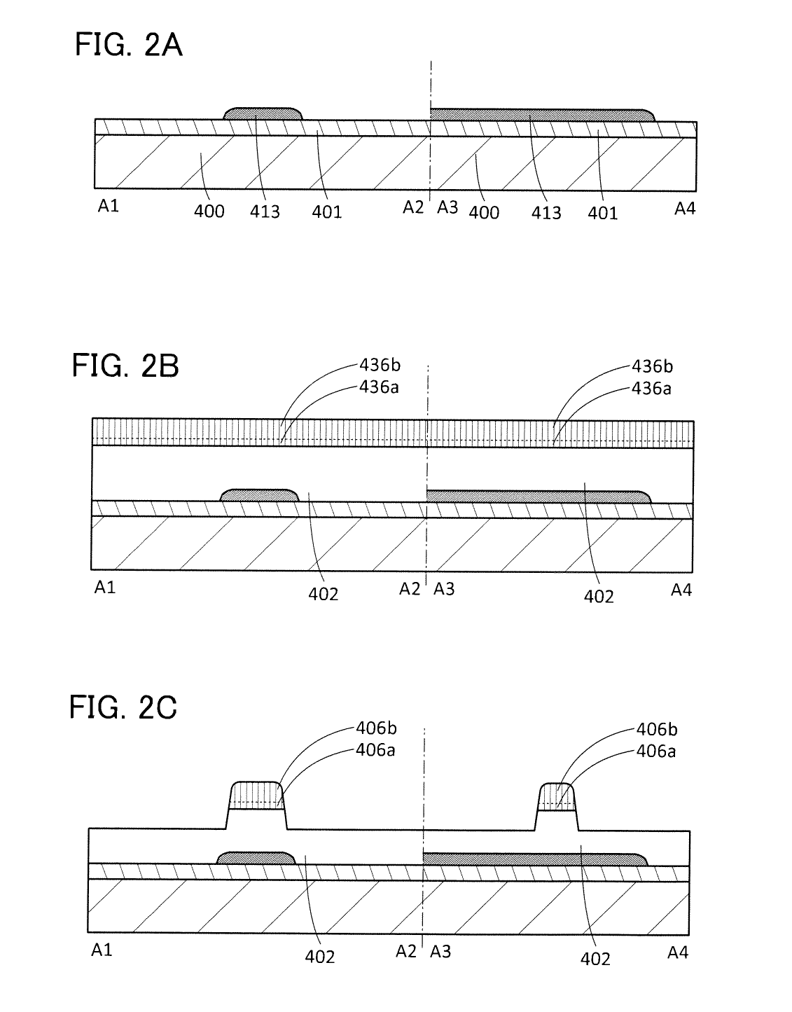

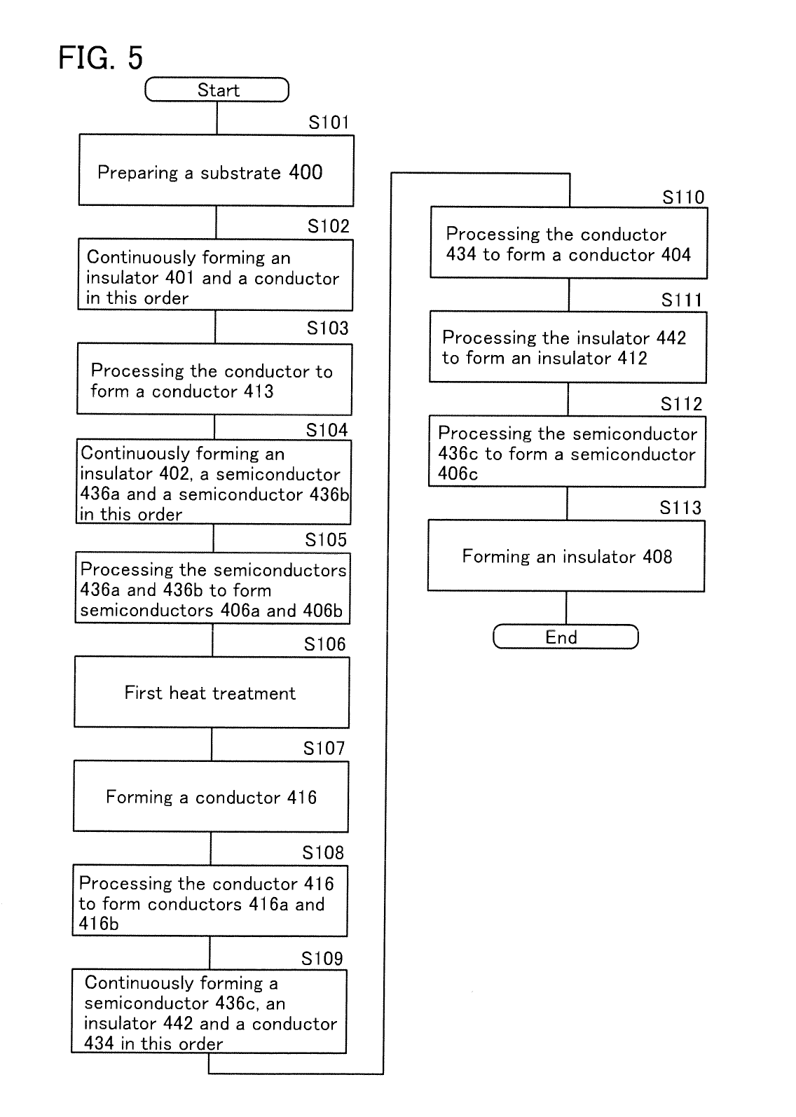

A method for manufacturing the transistor 490 described above is described below with reference to FIGS. 2A to 2C, FIGS. 3A to 3C, FIGS. 4A, 4B1, 4B2, and 4C, and FIG. 5.

First, the substrate 400 is prepared (see Step S101 in FIG. 5).

Next, the insulator 401 is formed over the substrate 400 (see Step S102 in FIG. 5). Note that the insulator 401 is preferably formed by a chemical vapor deposition (CVD) method or an atomic layer deposition (ALD) method. It is particularly preferable to use an MOCVD method.

CVD methods can be classified into a plasma enhanced CVD (PECVD) method using plasma, a thermal CVD (TCVD) method using heat, a photo CVD method using light, and the like. Moreover, the CVD methods can be further classified into a metal CVD (MCVD) method and a metal organic CVD (MOCVD) method according to a source gas to be used.

By using a PECVD method, a high-quality film can be formed at a relatively low temperature. Furthermore, a thermal CVD method does not use plasma and thus causes less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, when a thermal CVD method not using plasma is employed, such plasma damage is not caused and the yield of the semiconductor device can be increased. A thermal CVD method does not cause plasma damage during deposition, so that a film with few defects can be obtained.

An ALD method also causes less plasma damage to an object. An ALD method does not cause plasma damage during deposition, so that a film with few defects can be obtained.

Unlike in a deposition method in which particles ejected from a target or the like are deposited, in a CVD method and an ALD method, a film is formed by reaction at a surface of an object. Thus, a CVD method and an ALD method enable favorable step coverage almost regardless of the shape of an object. In particular, an ALD method enables excellent step coverage and excellent thickness uniformity and can be favorably used for covering a surface of an opening portion with a high aspect ratio, for example. On the other hand, an ALD method has a relatively low deposition rate; thus, it is sometimes preferable to combine an ALD method with another deposition method with a high deposition rate such as a CVD method.

When a CVD method or an ALD method is used, composition of a film to be formed can be controlled with a flow rate ratio of the source gases. For example, by a CVD method or an ALD method, a film with a certain composition can be formed depending on a flow rate ratio of the source gases. Moreover, with a CVD method or an ALD method, by changing the flow rate ratio of the source gases while forming the film, a film whose composition is continuously changed can be formed. In the case where the film is formed while changing the flow rate ratio of the source gases, as compared to the case where the film is formed using a plurality of deposition chambers, time taken for the film formation can be reduced because time taken for transfer and pressure adjustment is omitted. Thus, transistors can be manufactured with improved productivity in some cases. Specific examples of a deposition apparatus that can be used for an MOCVD method and a deposition apparatus that can be used for an ALD method are described later.

In some cases, a sputtering method, an MBE method, a PLD method, or an ALD method may be used, for example.

Next, a conductor is formed over the insulator 401 (see Step S102 in FIG. 5). The conductor is preferably formed by a CVD method or an ALD method. It is particularly preferable to use an MCVD method.

Here, it is preferable that the insulator 401 and the conductor be continuously formed without exposure to the air. In that case, entry of impurities into an interface can be inhibited.

In a clean room where semiconductor devices are manufactured or the like, impurities due to a clean filter (e.g., boron) might exist in the air. The impurities in the air such as boron lead to change in the properties of a semiconductor. It is thus preferable to inhibit entry of impurities into an unexpected portion of the semiconductor device to make the semiconductor device have favorable and stable electrical characteristics.

Note that continuously forming different films without exposure to the air is referred to as continuous film formation in this specification. Continuous film formation allows films to be formed by the same deposition method and/or in the same deposition chamber in some cases. Forming different films in the same deposition chamber increases the productivity of the semiconductor device in some cases. Note that continuous film formation is not limited to that performed in the same deposition chamber. Furthermore, continuous film formation is not limited to that performed by the same deposition method. In other words, continuous film formation can be performed by combining any of the above-described deposition methods.

Note that although the insulator 401 and the conductor are continuously formed in this example, the present invention is not limited thereto. For example, the insulator 401 and the conductor are not necessarily formed continuously in some cases.

Then, the conductor is processed to form the conductor 413 (see FIG. 2A and Step S103 in FIG. 5).

Note that the term “processing” in this specification means performing etching treatment using a resist mask that is formed by a photolithography method to obtain a desired shape.

Here, an example of a formation method of a resist mask is described. First, a layer of a photosensitive organic or inorganic substance to be the resist mask is formed by a spin coating method or the like. Next, the layer to be the resist mask is irradiated with light through a photomask. As such light, KrF excimer laser light, ArF excimer laser light, extreme ultraviolet (EUV) light, or the like may be used. Alternatively, a liquid immersion technique may be employed in which a portion between a substrate and a projection lens is filled with liquid (e.g., water) to perform light exposure. The layer to be the resist mask may be irradiated with an electron beam or an ion beam instead of the above light. Note that a photomask is not necessary in the case of using an electron beam or an ion beam. After that, a region of the layer to be the resist mask that has been exposed to light is removed or left with the use of a developer, so that the resist mask is formed. In the above manner, the resist mask can be formed.

Next, the insulator 402 is formed over the insulator 401 and the conductor 413 (see Step S104 in FIG. 5). The insulator 402 is preferably formed by a CVD method or an ALD method. It is particularly preferable to use a PECVD method or an MOCVD method.

Next, a semiconductor 436a is formed over the insulator 402 (see Step S104 in FIG. 5). The semiconductor 436a is preferably formed by a CVD method or an ALD method. It is particularly preferable to use an MOCVD method. At this time, by using an oxidizing gas such as oxygen or ozone as a reaction gas, excess oxygen can be added to the insulator 402 in some cases. Note that the semiconductor 436a is to be the semiconductor 406a illustrated in FIGS. 1A and 1B.

Next, a semiconductor 436b is formed over the semiconductor 436a (see FIG. 2B and Step S104 in FIG. 5). The semiconductor 436b is preferably formed by a CVD method or an ALD method. It is particularly preferable to use an MOCVD method. At this time, by using an oxidizing gas such as oxygen or ozone as a reaction gas, excess oxygen can be added to the insulator 402 and/or the semiconductor 436a in some cases. Note that the semiconductor 436b is to be the semiconductor 406b illustrated in FIGS. 1A and 1B.

When the insulator 402, the semiconductor 436a, and the semiconductor 436b are continuously formed, for example, entry of impurities into the interfaces can be inhibited. In other words, when the insulator 402, the semiconductor 436a, and the semiconductor 436b are continuously formed, the interface state density at the interfaces can be low. Formation of the insulator 402, the semiconductor 436a, and the semiconductor 436b by a film formation method causing less damage also enables low interface state density at the interfaces. Accordingly, the transistor 490 can have favorable and stable electrical characteristics. The insulator 402 functions as a gate insulator when the conductor 413 is used as a gate electrode. The semiconductor 436a also functions as a gate insulator in some cases.

Then, the semiconductor 436b is processed to form the semiconductor 406b (see Step S105 in FIG. 5).

Then, the semiconductor 436a is processed to form the semiconductor 406a (see FIG. 2C and Step S105 in FIG. 5).

Note that the semiconductor 436b and the semiconductor 436a may be processed through the same process. When the semiconductor 436b and the semiconductor 436a are processed through the same process, the productivity of the semiconductor device can be increased in some cases.

Note that in processing of the semiconductor 436a, part of the insulator 402 may be etched. That is, the insulator 402 may be provided with a projection in a region in contact with the semiconductor 406a and the semiconductor 406b (see FIG. 2C). When part of the insulator 402 has a projection, an s-channel structure can be easily formed in some cases.

Next, first heat treatment is preferably performed (see Step S106 in FIG. 5). The first heat treatment can be performed at a temperature higher than or equal to 250° C. and lower than or equal to 650° C., preferably higher than or equal to 450° C. and lower than or equal to 600° C., further preferably higher than or equal to 520° C. and lower than or equal to 570° C. The first heat treatment is performed in an inert gas atmosphere or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. By the first heat treatment, crystallinity of the semiconductor 406a and/or the semiconductor 406b can be increased and impurities such as hydrogen and water can be removed, for example. Note that the first heat treatment may be performed after the semiconductor 436b is formed and before the semiconductor 436b is processed. Note that in the case where heating at the time of formation of the layers doubles as the first heat treatment, the first heat treatment is not necessarily performed.

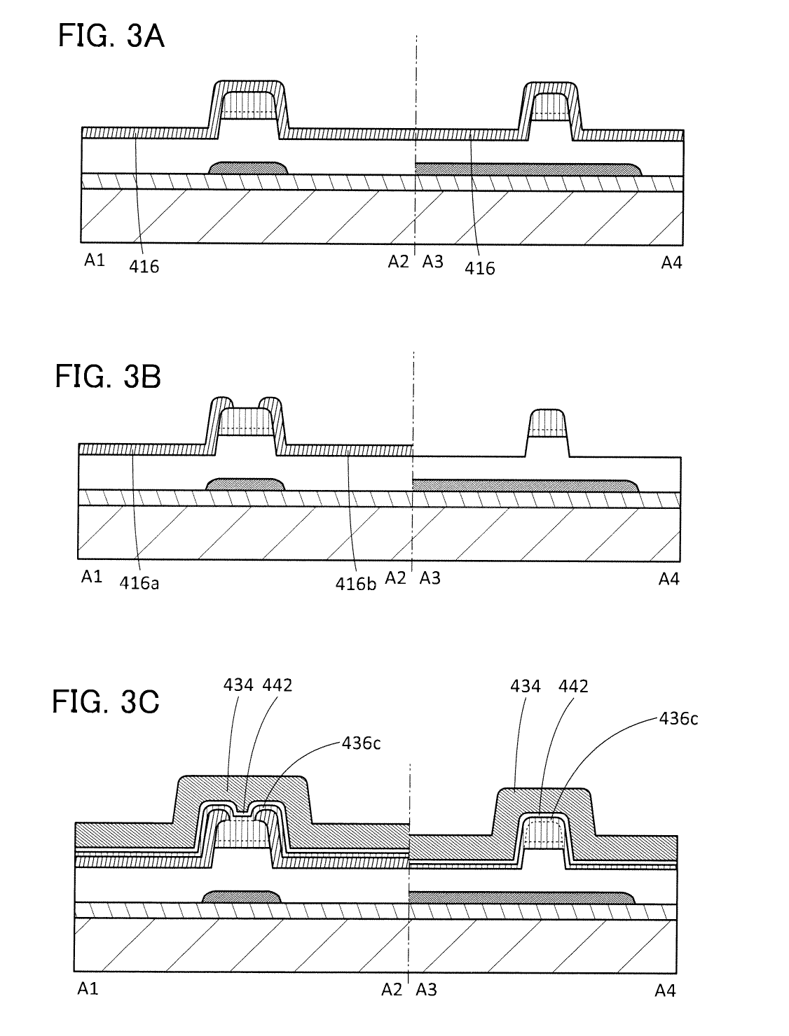

Next, a conductor 416 is formed over the insulator 402 and the semiconductor 406b (see FIG. 3A and Step S107 in FIG. 5). Note that the conductor 416 is to be the conductor 416a and the conductor 416b illustrated in FIGS. 1A and 1B.

The conductor 416 is preferably formed by a CVD method or an ALD method. It is particularly preferable to use an MCVD method. When the conductor 416 is formed by a CVD method or an ALD method, damage to the semiconductor 406b can be minimized. As a result, formation of a low-resistance region in the semiconductor 406b due to damage can be inhibited. It is also possible to inhibit formation of a mixed layer of the conductor 416 and the semiconductor 406b.

Then, the conductor 416 is processed to form the conductor 416a and the conductor 416b (see FIG. 3B and Step S108 in FIG. 5).

Next, a semiconductor 436c is formed over the insulator 402, the semiconductor 406b, the conductor 416a, and the conductor 416b (see Step S109 in FIG. 5). The semiconductor 436c is preferably formed by a CVD method or an ALD method. It is particularly preferable to use an MOCVD method. At this time, by using an oxidizing gas such as oxygen or ozone as a reaction gas, excess oxygen can be added to at least one of the insulator 402, the semiconductor 406a, and the semiconductor 406b in some cases. Note that the semiconductor 436c is to be the semiconductor 406c illustrated in FIGS. 1A and 1B.

Next, an insulator 442 is formed over the semiconductor 436c (see Step S109 in FIG. 5). The insulator 442 is preferably formed by a CVD method or an ALD method. It is particularly preferable to use an MOCVD method. At this time, by using an oxidizing gas such as oxygen or ozone as a reaction gas, excess oxygen can be added to at least one of the insulator 402, the semiconductor 406a, the semiconductor 406b, and the semiconductor 436c in some cases. Note that the insulator 442 is to be the insulator 412 illustrated in FIGS. 1A and 1B.

Next, a conductor 434 is formed over the insulator 442 (see FIG. 3C and Step S109 in FIG. 5). The conductor 434 is preferably formed by a CVD method or an ALD method. It is particularly preferable to use an MCVD method. Note that the conductor 434 is to be the conductor 404 illustrated in FIGS. 1A and 1B.

Here, it is preferred that the semiconductor 436c, the insulator 442, and the conductor 434 be continuously formed. In that case, entry of impurities into the interfaces can be inhibited. In other words, when the semiconductor 436c, the insulator 442, and the conductor 434 are continuously formed, the interface state density at the interfaces can be low. Formation of the semiconductor 436c, the insulator 442, and the conductor 434 by a film formation method causing less damage also enables low interface state density at the interfaces. Accordingly, the transistor 490 can have favorable and stable electrical characteristics. The insulator 442 to be the insulator 412 functions as a gate insulator when the conductor 434 to be the conductor 404 is used as a gate electrode. The semiconductor 436c also functions as a gate insulator in some cases.

Then, the conductor 434 is processed to form the conductor 404 (see Step S110 in FIG. 5).

Then, the insulator 442 is processed to form the insulator 412 (see Step S111 in FIG. 5).

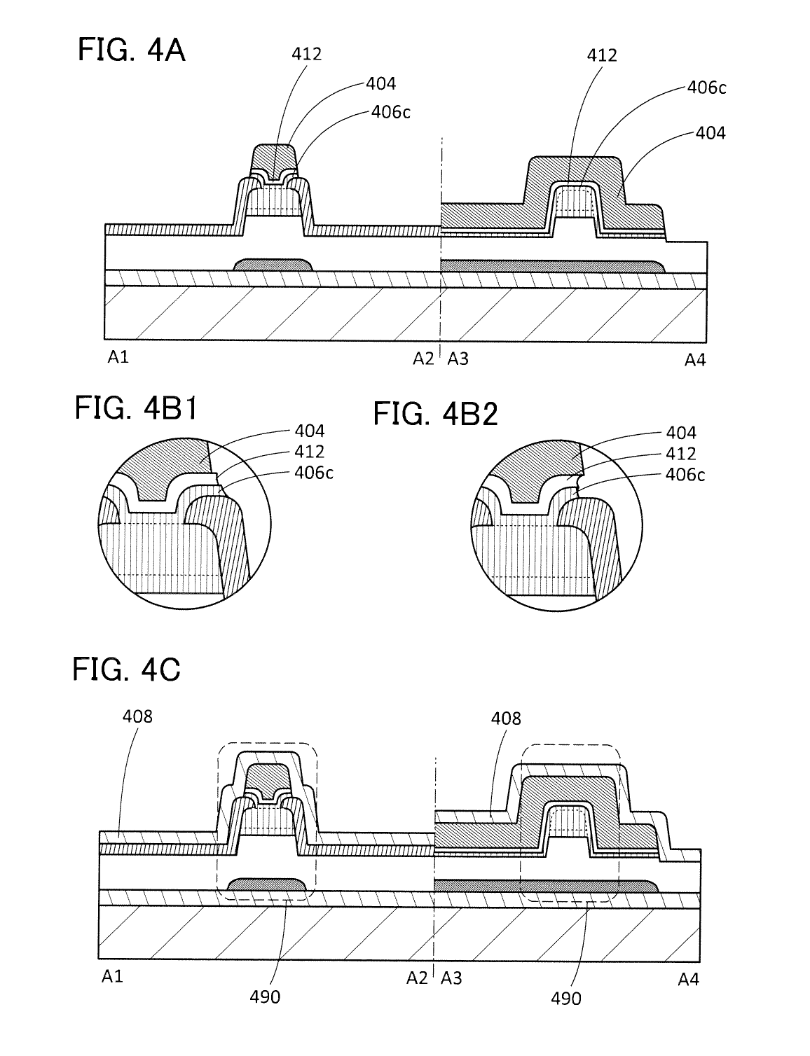

Then, the semiconductor 436c is processed to form the semiconductor 406c (see FIG. 4A and Step S112 in FIG. 5).

Note that the conductor 434, the insulator 442, and the semiconductor 436c may be processed through the same process. When the conductor 434, the insulator 442, and the semiconductor 436c are processed through the same process, the productivity of the semiconductor device can be increased in some cases.

The whole or part of the insulator 412, the semiconductor 406c, and the conductor 404 may be formed through different photolithography processes. In that case, the insulator 412 and/or the semiconductor 406c may project as compared with the conductor 404 as illustrated in the enlarged cross-sectional view in FIG. 4B 1 or the conductor 404 may project as compared with the insulator 412 and/or the semiconductor 406c as illustrated in the enlarged cross-sectional view in FIG. 4B2. With such a shape, shape defects are reduced and a gate leakage current can be reduced in some cases.

Although the conductor 404, the insulator 412, and the semiconductor 406c have the same shape in a top view in this example, the present invention is not limited thereto. For example, the insulator 442 and/or the semiconductor 436c may be used without being processed in some cases.

Next, the insulator 408 is formed over the insulator 402, the conductor 416a, the conductor 416b, and the conductor 404 (see FIG. 4C and Step S113 in FIG. 5). The insulator 408 is preferably formed by a CVD method or an ALD method. It is particularly preferable to use an MOCVD method.

Through the above steps, the transistor 490 can be manufactured. The transistor 490 has favorable and stable electrical characteristics because impurities do not easily enter the interfaces between the layers and damage to the layers due to deposition is limited.

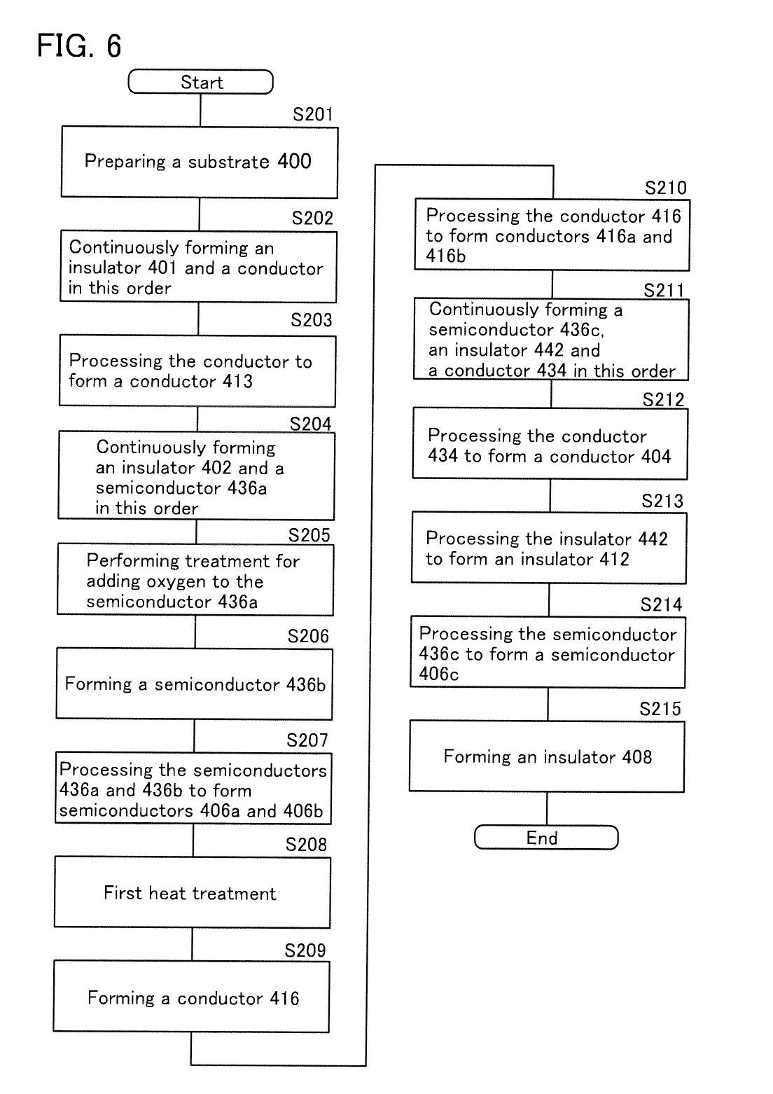

The transistor 490 can also be fabricated in accordance with the flow chart in FIG. 6.

The flow chart in FIG. 6 is different from the flow chart in FIG. 5 in that it includes a step of performing treatment for adding oxygen to the semiconductor 436a after formation of the semiconductor 436a (see Step S205 in FIG. 6). For Steps S201 to S215 in FIG. 6, the description of Steps S101 to S113 in FIG. 5 can be referred to as appropriate.

Examples of the treatment for adding oxygen to the semiconductor 436a include ion implantation and plasma treatment. Note that oxygen added to the semiconductor 436a becomes excess oxygen.

In ion implantation, a gas containing oxygen atoms is used as a source gas and acceleration voltage is applied to an object. Note that as a gas containing oxygen atoms, for example, an oxygen gas, an ozone gas, a carbon monoxide gas, a carbon dioxide gas, a nitrous oxide gas, a nitrogen monoxide gas, or a nitrogen dioxide gas can be used. Specifically, an oxygen gas is preferably used.

In ion implantation, it is possible to use ions that are mass-separated or those that are not mass-separated. The use of mass-separated ions can reduce variation in implantation depth, in-plane variation, or the like. With the same acceleration voltage used, mass-separated O₂⁺ ions can be implanted in a shallower region than O⁺ ions, for example. Therefore, in the case where the semiconductor 436a is thin, it might be preferable to use mass-separated O₂⁺ ions. In that case, entry of impurities can also be reduced. When ions that are not mass-separated are used, a high dose of ions can be implanted in a short time. Thus, when the dose should be high, ions that are not mass-separated are preferably used in some cases.

In plasma treatment, for example, high-frequency power is applied to an object to generate plasma, ions containing oxygen in the plasma are accelerated with self-bias voltage, and thus, oxygen can be added. Note that inductively coupled plasma or the like may be used.

Note that the treatment for adding oxygen may be performed on not only the semiconductor 436a but also the insulator 402. For example, oxygen may be added to the insulator 402 through the semiconductor 436a.

After the treatment for adding oxygen to the semiconductor 436a, the semiconductor 436b is formed over the semiconductor 436a (see FIG. 2B and Step S206 in FIG. 6).

Note that it is preferable that formation of the semiconductor 436a, the treatment for adding oxygen, and formation of the semiconductor 436b be performed continuously without exposure to the air. In that case, entry of impurities into an interface can be inhibited.

Then, the semiconductor 436b is processed to form the semiconductor 406b (see Step S207 in FIG. 6).

Then, the semiconductor 436a is processed to form the semiconductor 406a (see FIG. 2C and Step S207 in FIG. 6).

Next, first heat treatment is preferably performed (see Step S208 in FIG. 6). The first heat treatment can be performed at a temperature higher than or equal to 250° C. and lower than or equal to 650° C., preferably higher than or equal to 450° C. and lower than or equal to 600° C., further preferably higher than or equal to 520° C. and lower than or equal to 570° C. The first heat treatment is performed in an inert gas atmosphere or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. By the first heat treatment, crystallinity of the semiconductor 406a and/or the semiconductor 406b can be increased and impurities such as hydrogen and water can be removed, for example. Note that the first heat treatment may be performed after the semiconductor 436b is formed and before the semiconductor 436b is processed. Note that in the case where heating at the time of formation of the layers doubles as the first heat treatment, the first heat treatment is not necessarily performed.

Here, when the semiconductor 406a contains oxygen (excess oxygen), oxygen vacancies in the semiconductor 406b can be reduced in some cases. The semiconductor 406a is closer to the semiconductor 406b than the insulator 402 is. Thus, when the semiconductor 406a contains excess oxygen, oxygen vacancies in the semiconductor 406b can be reduced more effectively than when the insulator 402 contains excess oxygen.

Furthermore, for example, when the insulator 402 is silicon oxide or silicon oxynitride, excess oxygen is diffused in a wide area by heat treatment. By contrast, in the semiconductor 406a, the distance to which excess oxygen is diffused by heat treatment is shorter than in silicon oxide, silicon oxynitride, or the like; thus, the temperature of the first heat treatment can be high. Since the temperature of the first heat treatment can be high, impurities contained in the semiconductor 406a and/or the semiconductor 406b can be reduced. In addition, the crystallinity of the semiconductor 406a and/or the semiconductor 406b can be high in some cases.

Note that an oxynitride in this specification refers to an oxide containing nitrogen at a concentration higher than or equal to 0.1 atomic % and less than 25 atomic %. A nitride oxide in this specification is a nitride containing oxygen at a concentration higher than or equal to 0.1 atomic % and less than 25 atomic %. For example, silicon oxynitride is an oxynitride, and silicon nitride oxide is a nitride oxide.

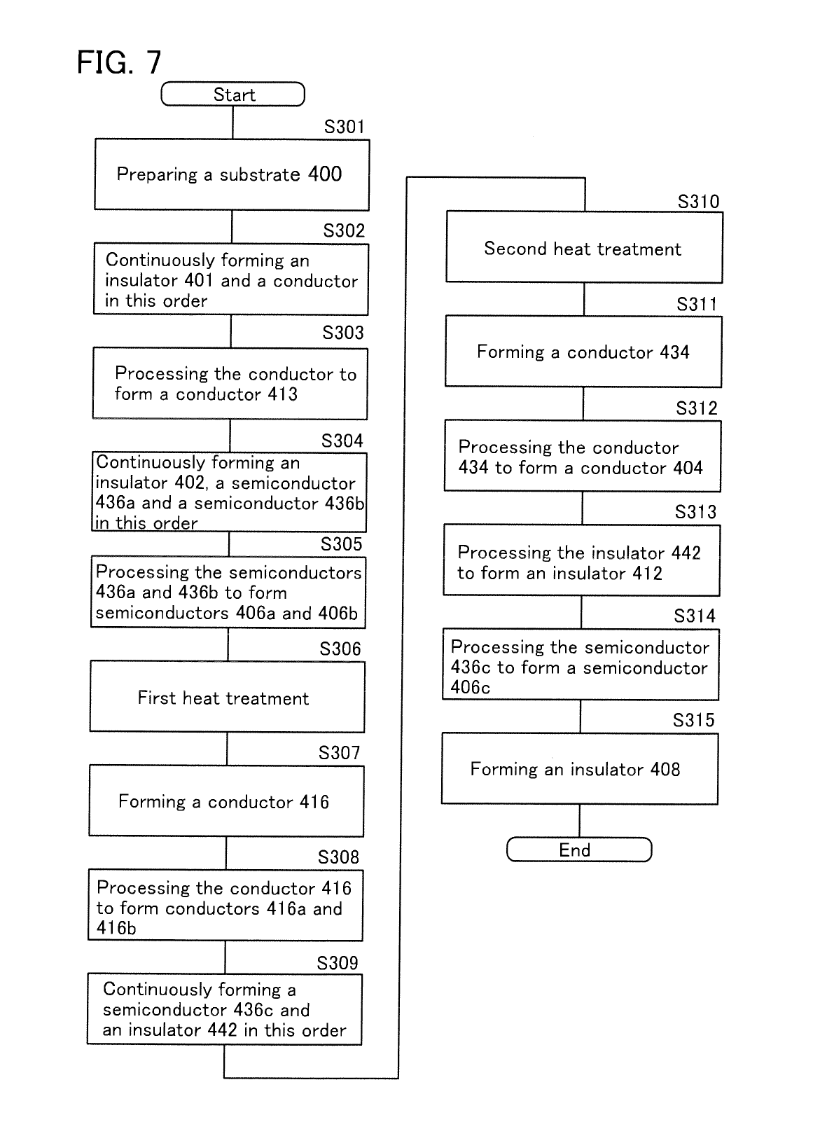

The transistor 490 can also be fabricated in accordance with the flow chart in FIG. 7.

The flow chart in FIG. 7 is different from the flow chart in FIG. 5 in that it includes a step of performing second heat treatment after formation of the insulator 442 (see Step S310 in FIG. 7). For Steps S301 to S315 in FIG. 7, the description of Steps S101 to S113 in FIG. 5 can be referred to as appropriate.

By performing the second heat treatment after formation of the insulator 442, excess oxygen in the insulator 402 and/or the semiconductor 436a is moved to the semiconductor 406b. The semiconductor 406b is covered with the semiconductor 436c; thus, outward diffusion of excess oxygen is less likely to occur. Therefore, by performing the second heat treatment at this time, defects (oxygen vacancies) in the semiconductor 406b can be efficiently reduced. Note that the second heat treatment may be performed at a temperature such that excess oxygen (oxygen) in the insulator 402 and/or the semiconductor 436a is diffused to the semiconductor 406b. For example, the description of the first heat treatment may be referred to for the second heat treatment. The second heat treatment is preferably performed at a temperature lower than that of the first heat treatment. The difference between the temperature of the first heat treatment and that of the second heat treatment is higher than or equal to 20° C. and lower than or equal to 150° C., preferably higher than or equal to 40° C. and lower than or equal to 100° C. Accordingly, superfluous release of excess oxygen (oxygen) from the insulator 402 and/or the semiconductor 436a can be inhibited. Note that in the case where heating at the time of formation of the layers doubles as the second heat treatment, the second heat treatment is not necessarily performed.

After the second heat treatment, the conductor 434 is formed over the insulator 442 (see FIG. 3C and Step S311 in FIG. 7).

Note that it is preferable that formation of the insulator 442, the second heat treatment, and formation of the conductor 434 be performed continuously without exposure to the air. In that case, entry of impurities into an interface can be inhibited.

Then, the conductor 434 is processed to form the conductor 404 (see Step S312 in FIG. 7).

Then, the insulator 442 is processed to form the insulator 412 (see Step S313 in FIG. 7).

Then, the semiconductor 436c is processed to form the semiconductor 406c (see FIG. 4A and Step S314 in FIG. 7).

Note that the manufacturing methods of the transistor 490 in FIGS. 5 to 7 may be used in combination. For example, the manufacturing method in FIG. 7 may include the treatment for adding oxygen shown in FIG. 6.

### <Transistor Structure 2>

An example of a transistor different from the transistor 490 shown in FIGS. 1A and 1B and the like is described.

Although FIGS. 1A and 1B and the like show an example where the conductor 416a and the conductor 416b which function as a source electrode and a drain electrode are in contact with a top surface and a side surface of the semiconductor 406b, a top surface of the insulator 402, and the like, a transistor structure of one embodiment of the present invention is not limited thereto.

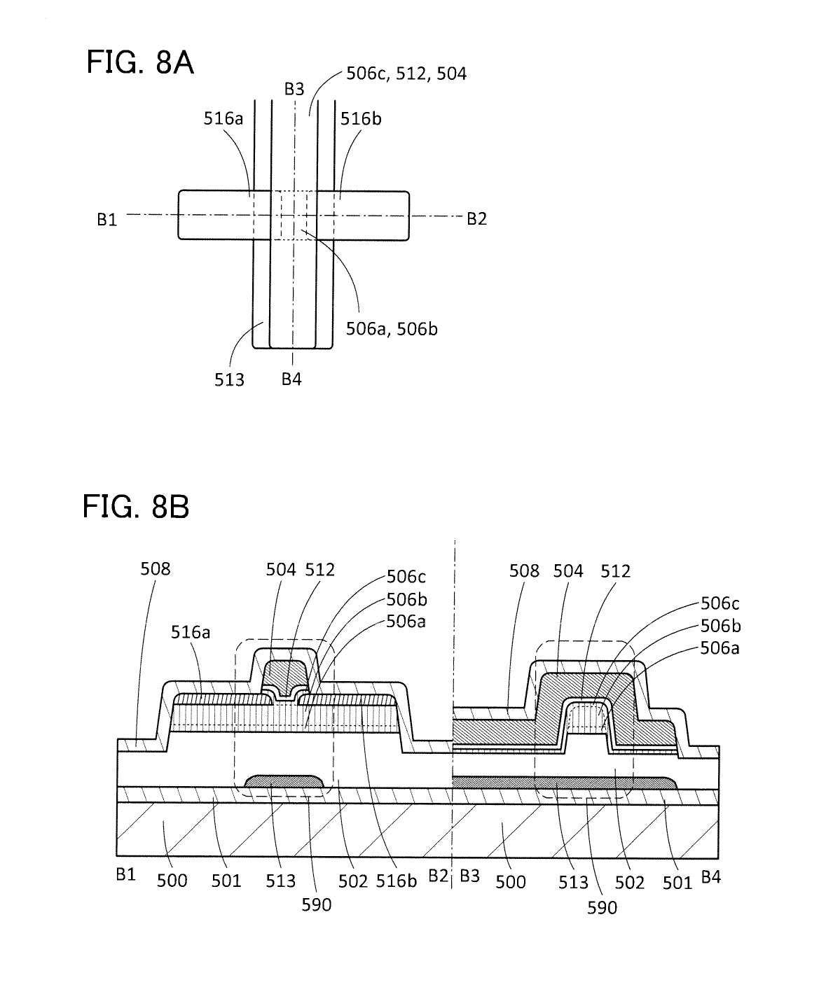

FIG. 8A is an example of a top view of a transistor 590. FIG. 8B is an example of a cross-sectional view taken along dashed-dotted line B1-B2 and dashed-dotted line B3-B4 in FIG. 8A. Note that some components such as an insulator are omitted in FIG. 8A for easy understanding.

For a substrate 500, the description of the substrate 400 is referred to. For an insulator 501, the description of the insulator 401 is referred to. For a conductor 513, the description of the conductor 413 is referred to. For an insulator 502, the description of the insulator 402 is referred to. For a semiconductor 506a, the description of the semiconductor 406a is referred to. For a semiconductor 506b, the description of the semiconductor 406b is referred to. For a conductor 516a and a conductor 516b, the description of the conductor 416a and the conductor 416b is referred to. For a semiconductor 506c, the description of the semiconductor 406c is referred to. For an insulator 512, the description of the insulator 412 is referred to. For a conductor 504, the description of the conductor 404 is referred to. For an insulator 508, the description of the insulator 408 is referred to.

In the transistor illustrated in FIGS. 8A and 8B, the conductor 516a and the conductor 516b are not in contact with side surfaces of the semiconductor 506b. Thus, an electric field applied from the conductor 504 functioning as a first gate electrode to the side surfaces of the semiconductor 506b is less likely to be blocked by the conductor 516a and the conductor 516b. The conductor 516a and the conductor 516b are not in contact with a top surface of the insulator 502. Thus, excess oxygen (oxygen) released from the insulator 502 is not consumed to oxidize the conductor 516a and the conductor 516b. Accordingly, excess oxygen (oxygen) released from the insulator 502 can be efficiently used to reduce oxygen vacancies in the semiconductor 506b. In other words, the transistor having the structure illustrated in FIGS. 8A and 8B has excellent electrical characteristics such as a high on-state current, high field-effect mobility, a small subthreshold swing value, and high reliability.

### <Method for Manufacturing Transistor Structure 2>

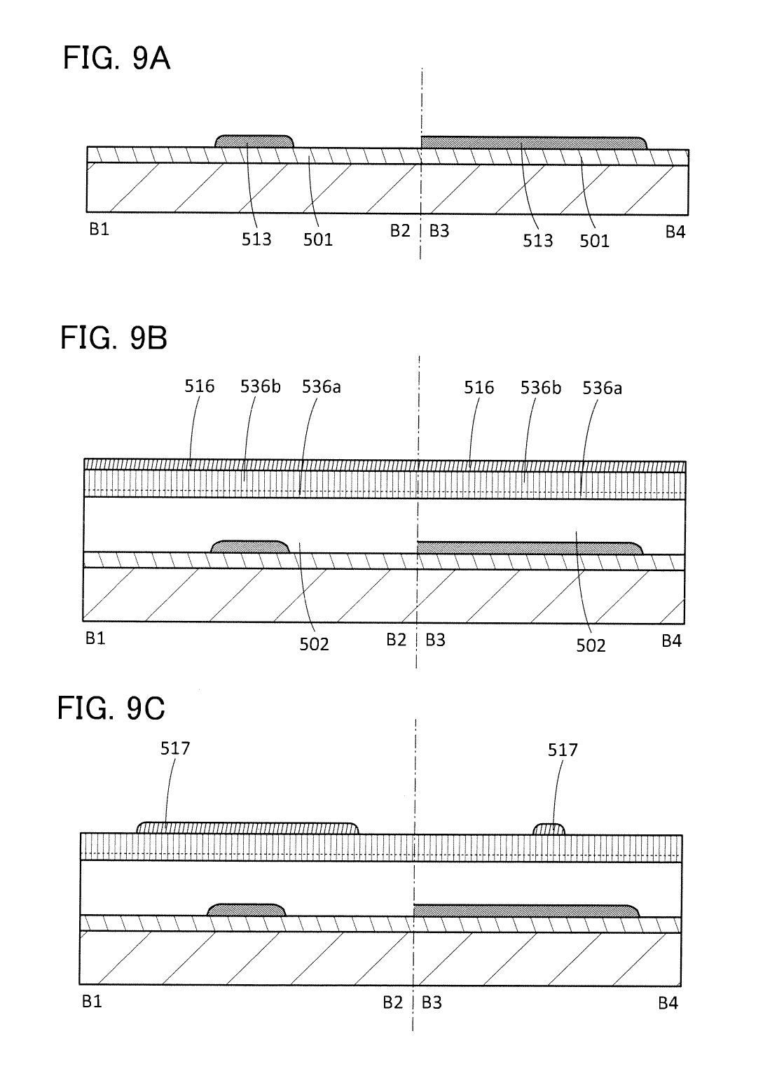

A method for manufacturing the transistor 590 described above is described below with reference to FIGS. 9A to 9C, FIGS. 10A to 10C, FIGS. 11A and 11B, and FIG. 12.

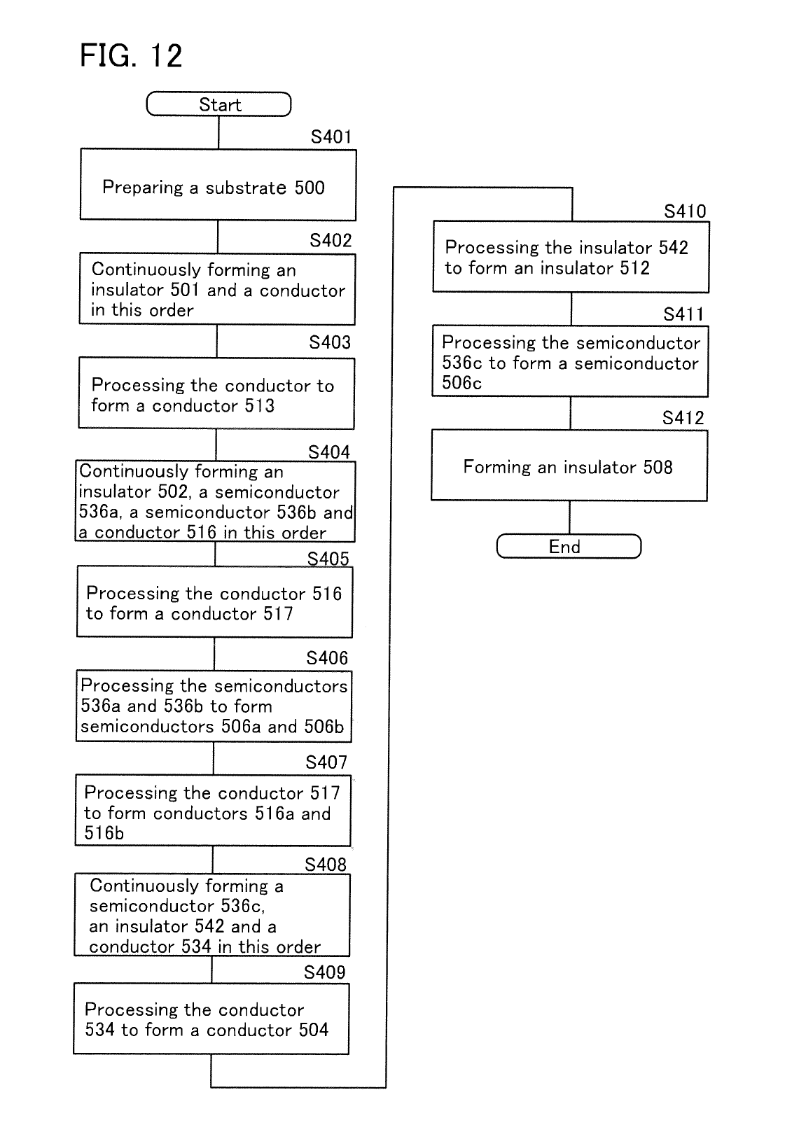

First, the substrate 500 is prepared (see Step S401 in FIG. 12).

Next, the insulator 501 is formed over the substrate 500 (see Step S402 in FIG. 12). Note that the insulator 501 is preferably formed by a CVD method or an ALD method. It is particularly preferable to use an MOCVD method.

Next, a conductor is formed over the insulator 501 (see Step S402 in FIG. 12). The conductor is preferably formed by a CVD method or an ALD method. It is particularly preferable to use an MCVD method.

Here, it is preferable that the insulator 501 and the conductor be continuously formed without exposure to the air. In that case, entry of impurities into an interface can be inhibited.

Note that although the insulator 501 and the conductor are continuously formed in this example, the present invention is not limited thereto. For example, the insulator 501 and the conductor are not necessarily formed continuously in some cases.

Then, the conductor is processed to form the conductor 513 (see FIG. 9A and Step S403 in FIG. 12).

Next, the insulator 502 is formed over the insulator 501 and the conductor 513 (see Step S404 in FIG. 12). The insulator 502 is preferably formed by a CVD method or an ALD method. It is particularly preferable to use a PECVD method or an MOCVD method.

Next, a semiconductor 536a is formed over the insulator 502 (see Step S404 in FIG. 12). The semiconductor 536a is preferably formed by a CVD method or an ALD method. It is particularly preferable to use an MOCVD method. At this time, by using an oxidizing gas such as oxygen or ozone as a reaction gas, excess oxygen can be added to the insulator 502 in some cases. Note that the semiconductor 536a is to be the semiconductor 506a illustrated in FIGS. 8A and 8B.

Next, a semiconductor 536b is formed over the semiconductor 536a (see Step S404 in FIG. 12). The semiconductor 536b is preferably formed by a CVD method or an ALD method. It is particularly preferable to use an MOCVD method. At this time, by using an oxidizing gas such as oxygen or ozone as a reaction gas, excess oxygen can be added to the insulator 502 and/or the semiconductor 536a in some cases. Note that the semiconductor 536b is to be the semiconductor 506b illustrated in FIGS. 8A and 8B.

Next, a conductor 516 is formed over the semiconductor 536b (see FIG. 9B and Step S404 in FIG. 12). Note that the conductor 516 is to be the conductor 516a and the conductor 516b illustrated in FIGS. 8A and 8B.

The conductor 516 is preferably formed by a CVD method or an ALD method. It is particularly preferable to use an MCVD method. When the conductor 516 is formed by a CVD method or an ALD method, damage to the semiconductor 536b can be minimized. As a result, formation of a low-resistance region in the semiconductor 536b due to damage can be inhibited. It is also possible to inhibit formation of a mixed layer of the conductor 516 and the semiconductor 536b.

When the insulator 502, the semiconductor 536a, the semiconductor 536b, and the conductor 516 are continuously formed, for example, entry of impurities into the interfaces can be inhibited. In other words, when the insulator 502, the semiconductor 536a, the semiconductor 536b, and the conductor 516 are continuously formed, the interface state density at the interfaces can be low. Formation of the insulator 502, the semiconductor 536a, the semiconductor 536b, and the conductor 516 by a film formation method causing less damage also enables low interface state density at the interfaces. Accordingly, the transistor 590 can have favorable and stable electrical characteristics. The insulator 502 functions as a gate insulator when the conductor 513 is used as a gate electrode. The semiconductor 536a also functions as a gate insulator in some cases.

Then, the conductor 516 is processed to form the conductor 517 (see FIG. 9C and Step S405 in FIG. 12). The conductor 517 functions as a hard mask.

Then, the semiconductor 536b is processed to form the semiconductor 506b (see Step S406 in FIG. 12).

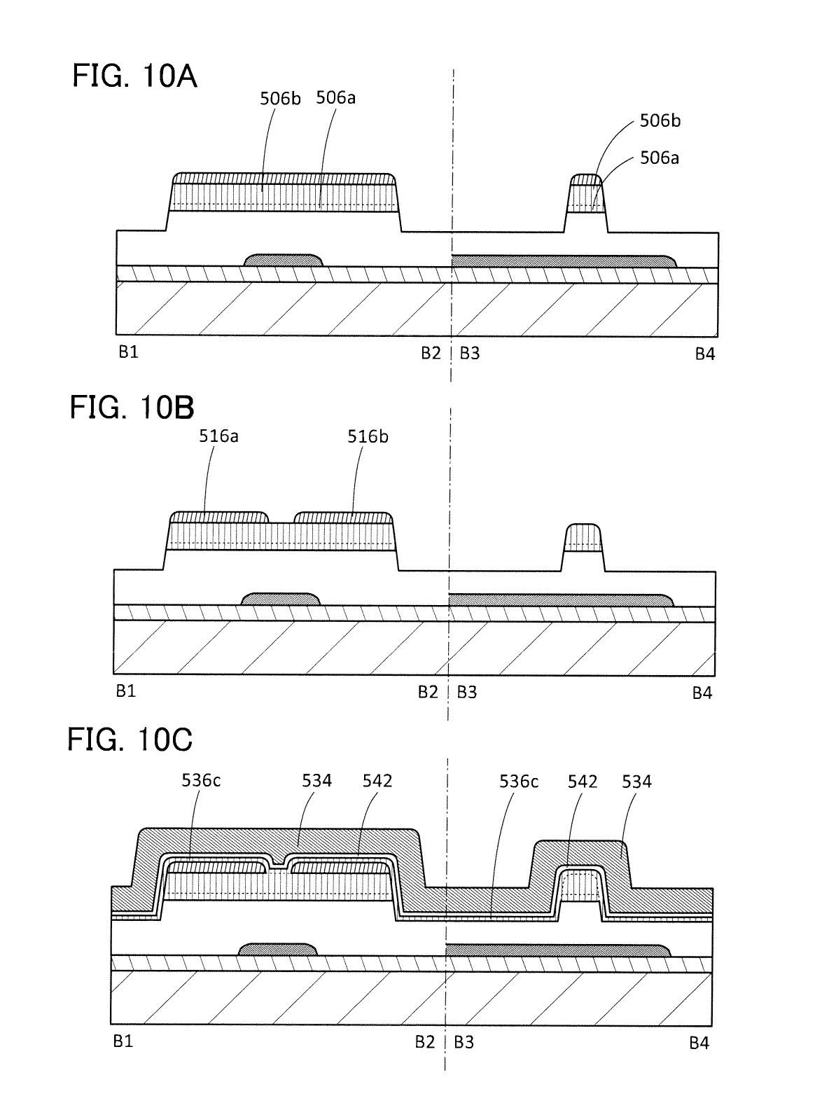

Then, the semiconductor 536a is processed to form the semiconductor 506a (see FIG. 10A and Step S406 in FIG. 12).

Note that some or all of the conductor 516, the semiconductor 536b, and the semiconductor 536a may be processed through the same process. When some or all of the conductor 516, the semiconductor 536b, and the semiconductor 536a are processed through the same process, the productivity of the semiconductor device can be increased in some cases.

Note that in processing of the semiconductor 536a, part of the insulator 502 may be etched. That is, the insulator 502 may be provided with a projection in a region in contact with the semiconductor 506a and the semiconductor 506b (see FIG. 10A). When part of the insulator 502 has a projection, an s-channel structure can be easily formed in some cases.

Then, the conductor 517 is processed to form the conductor 516a and the conductor 516b (see FIG. 10B and Step S407 in FIG. 12).

Next, a semiconductor 536c is formed over the insulator 502, the semiconductor 506b, the conductor 516a, and the conductor 516b (see Step S408 in FIG. 12). The semiconductor 536c is preferably formed by a CVD method or an ALD method. It is particularly preferable to use an MOCVD method. At this time, by using an oxidizing gas such as oxygen or ozone as a reaction gas, excess oxygen can be added to at least one of the insulator 502, the semiconductor 506a, and the semiconductor 506b in some cases. Note that the semiconductor 536c is to be the semiconductor 506c illustrated in FIGS. 8A and 8B.

Next, an insulator 542 is formed over the semiconductor 536c (see Step S408 in FIG. 12). The insulator 542 is preferably formed by a CVD method or an ALD method. It is particularly preferable to use an MOCVD method. At this time, by using an oxidizing gas such as oxygen or ozone as a reaction gas, excess oxygen can be added to at least one of the insulator 502, the semiconductor 506a, the semiconductor 506b, and the semiconductor 536c in some cases. Note that the insulator 542 is to be the insulator 512 illustrated in FIGS. 8A and 8B.

Next, a conductor 534 is formed over the insulator 542 (see FIG. 10C and Step S408 in FIG. 12). The conductor 534 is preferably formed by a CVD method or an ALD method. It is particularly preferable to use an MCVD method. Note that the conductor 534 is to be the conductor 504 illustrated in FIGS. 8A and 8B.

Here, it is preferred that the semiconductor 536c, the insulator 542, and the conductor 534 be continuously formed. In that case, entry of impurities into the interfaces can be inhibited. In other words, when the semiconductor 536c, the insulator 542, and the conductor 534 are continuously formed, the interface state density at the interfaces can be low. Formation of the semiconductor 536c, the insulator 542, and the conductor 534 by a film formation method causing less damage also enables low interface state density at the interfaces. Accordingly, the transistor 590 can have favorable and stable electrical characteristics. The insulator 542 to be the insulator 512 functions as a gate insulator when the conductor 534 to be the conductor 504 is used as a gate electrode. The semiconductor 536c also functions as a gate insulator in some cases.

Then, the conductor 534 is processed to form the conductor 504 (see Step S409 in FIG. 12).

Then, the insulator 542 is processed to form the insulator 512 (see Step S410 in FIG. 12).

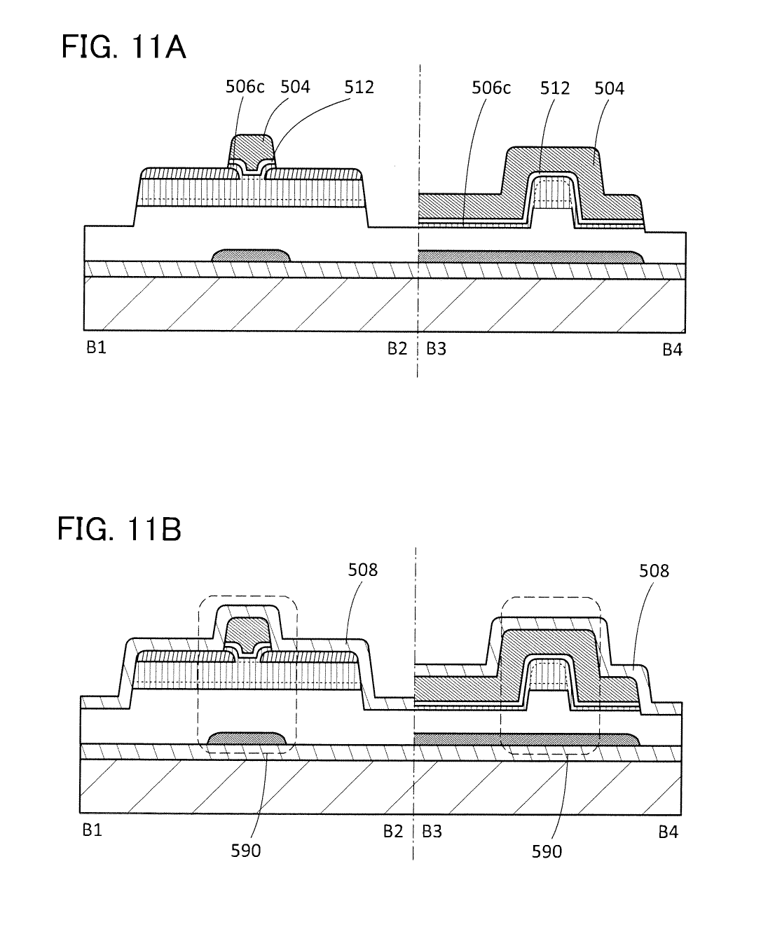

Then, the semiconductor 536c is processed to form the semiconductor 506c (see FIG. 11A and Step S411 in FIG. 12).

Note that the conductor 534, the insulator 542, and the semiconductor 536c may be processed through the same process. When the conductor 534, the insulator 542, and the semiconductor 536c are processed through the same process, the productivity of the semiconductor device can be increased in some cases.

The whole or part of the insulator 512, the semiconductor 506c, and the conductor 504 may be formed through different photolithography processes. In that case, the insulator 512 and/or the semiconductor 506c may project as compared with the conductor 504, or the conductor 504 may project as compared with the insulator 512 and/or the semiconductor 506c. With such a shape, shape defects are reduced and a gate leakage current can be reduced in some cases.

Although the conductor 504, the insulator 512, and the semiconductor 506c have the same shape in a top view in this example, the present invention is not limited thereto. For example, the insulator 542 and/or the semiconductor 536c may be used without being processed in some cases.

Next, the insulator 508 is formed over the insulator 502, the conductor 516a, the conductor 516b, and the conductor 504 (see FIG. 11B and Step S412 in FIG. 12). The insulator 508 is preferably formed by a CVD method or an ALD method. It is particularly preferable to use an MOCVD method.

Through the above steps, the transistor 590 can be manufactured. The transistor 590 has favorable and stable electrical characteristics because impurities do not easily enter the interfaces between the layers and damage to the layers due to deposition is limited.

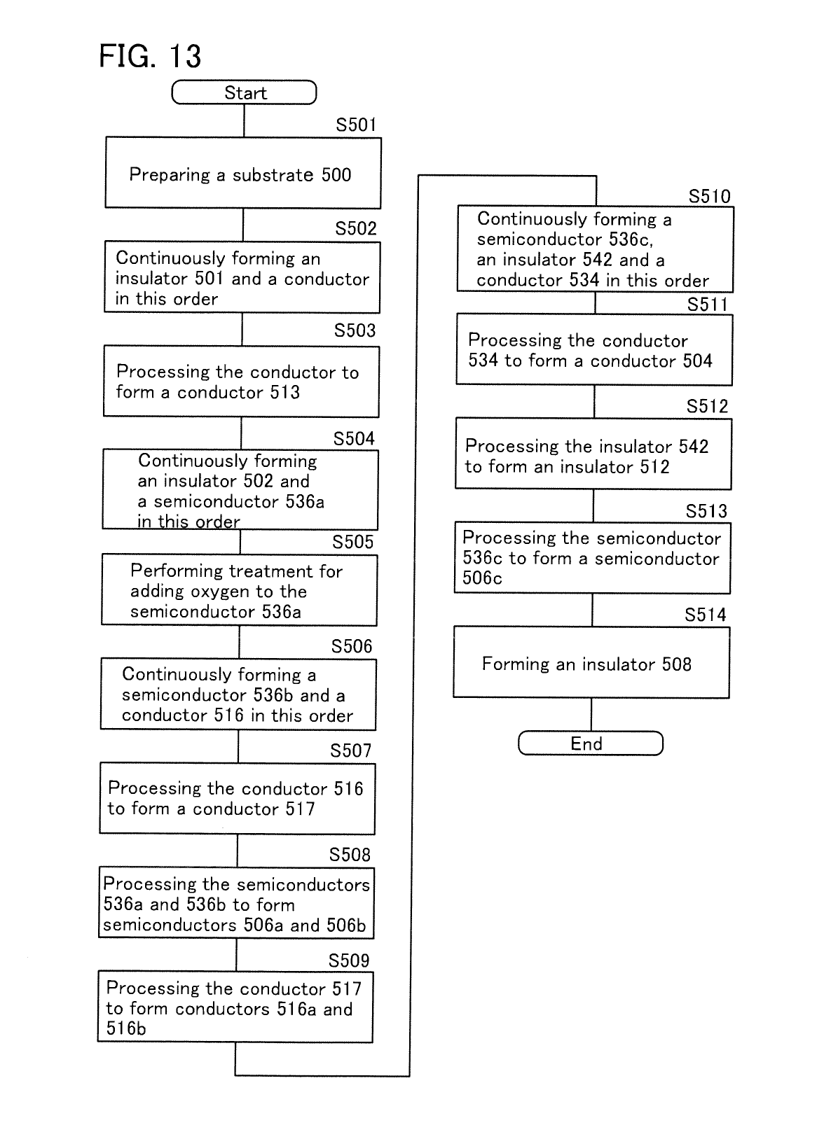

The transistor 590 can also be fabricated in accordance with the flow chart in FIG. 13.

The flow chart in FIG. 13 is different from the flow chart in FIG. 12 in that it includes a step of performing treatment for adding oxygen to the semiconductor 536a after formation of the semiconductor 536a (see Step S505 in FIG. 13). For Steps S501 to S515 in FIG. 13, the description of Steps S401 to S413 in FIG. 12 can be referred to as appropriate.

Examples of the treatment for adding oxygen to the semiconductor 536a include ion implantation and plasma treatment. Note that oxygen added to the semiconductor 536a becomes excess oxygen. For the treatment for adding oxygen to the semiconductor 536a, the treatment for adding oxygen to the semiconductor 436a is referred to.

Note that the treatment for adding oxygen may be performed on not only the semiconductor 536a but also the insulator 502. For example, oxygen may be added to the insulator 502 through the semiconductor 536a.

After the treatment for adding oxygen to the semiconductor 536a, the semiconductor 536b is formed over the semiconductor 536a (see Step S506 in FIG. 13).

Note that it is preferable that formation of the semiconductor 536a, the treatment for adding oxygen, and formation of the semiconductor 536b be performed continuously without exposure to the air. In that case, entry of impurities into an interface can be inhibited.

Next, the conductor 516 is formed over the semiconductor 536b (see Step S506 in FIG. 13).

When the semiconductor 536b and the conductor 516 are continuously formed, entry of impurities into the interface therebetween can be inhibited. In other words, when the semiconductor 536b and the conductor 516 are continuously formed, the interface state density at the interface therebetween can be low. Formation of the semiconductor 536b and the conductor 516 by a film formation method causing less damage also enables low interface state density at the interface.

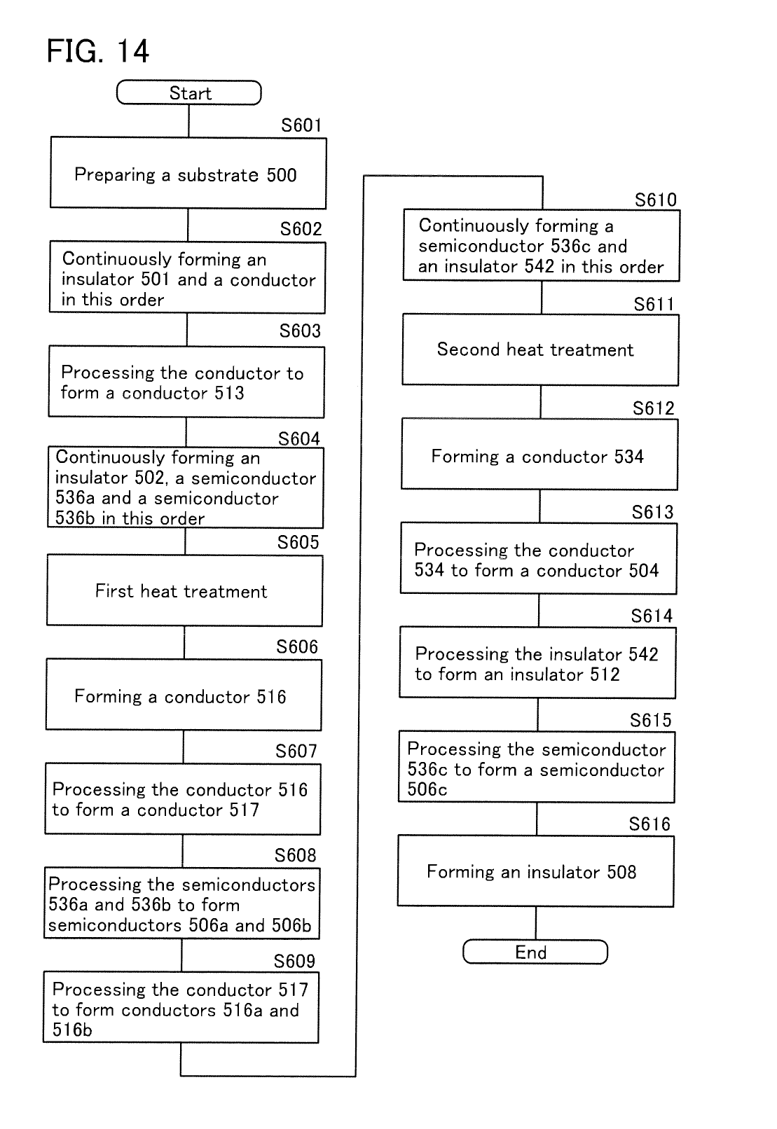

The transistor 590 can also be fabricated in accordance with the flow chart in FIG. 14.

The flow chart in FIG. 14 is different from the flow chart in FIG. 12 in that it includes a step of performing first heat treatment after formation of the semiconductor 536b and a step of performing second heat treatment after formation of the insulator 542 (see Steps S605 and S611 in FIG. 14). For Steps S601 to S615 in FIG. 14, the description of Steps S401 to S413 in FIG. 12 can be referred to as appropriate.

The first heat treatment can be performed at a temperature higher than or equal to 250° C. and lower than or equal to 650° C., preferably higher than or equal to 450° C. and lower than or equal to 600° C., further preferably higher than or equal to 520° C. and lower than or equal to 570° C. The first heat treatment is performed in an inert gas atmosphere or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. By the first heat treatment, crystallinity of the semiconductor 536a and/or the semiconductor 536b can be increased and impurities such as hydrogen and water can be removed, for example. Note that in the case where heating at the time of formation of the layers doubles as the first heat treatment, the first heat treatment is not necessarily performed.

After the first heat treatment, the conductor 516 is formed over the semiconductor 536 (see FIG. 9B and Step S606 in FIG. 14).

By performing the second heat treatment after formation of the insulator 542, excess oxygen in the insulator 502 and/or the semiconductor 536a is moved to the semiconductor 506b. The semiconductor 506b is covered with the semiconductor 536c; thus, outward diffusion of excess oxygen is less likely to occur. Therefore, by performing the second heat treatment at this time, defects (oxygen vacancies) in the semiconductor 506b can be efficiently reduced. Note that the second heat treatment may be performed at a temperature such that excess oxygen (oxygen) in the insulator 502 and/or the semiconductor 536a is diffused to the semiconductor 506b. For example, the description of the first heat treatment may be referred to for the second heat treatment. The second heat treatment is preferably performed at a temperature lower than that of the first heat treatment. The difference between the temperature of the first heat treatment and that of the second heat treatment is higher than or equal to 20° C. and lower than or equal to 150° C., preferably higher than or equal to 40° C. and lower than or equal to 100° C. Accordingly, superfluous release of excess oxygen (oxygen) from the insulator 502 can be inhibited. Note that in the case where heating at the time of formation of the layers doubles as the second heat treatment, the second heat treatment is not necessarily performed.

After the second heat treatment, the conductor 534 is formed over the insulator 542 (see FIG. 10C and Step S612 in FIG. 14).

Note that it is preferable that formation of the insulator 542, the second heat treatment, and formation of the conductor 534 be performed continuously without exposure to the air. In that case, entry of impurities into an interface can be inhibited.

Then, the conductor 534 is processed to form the conductor 504 (see Step S613 in FIG. 14).

Then, the insulator 542 is processed to form the insulator 512 (see Step S614 in FIG. 14).

Then, the semiconductor 536c is processed to form the semiconductor 506c (see FIG. 11A and Step S615 in FIG. 14).

Note that the manufacturing methods of the transistor 590 in FIGS. 12 to 14 may be used in combination. For example, the manufacturing method in FIG. 14 may include the treatment for adding oxygen shown in FIG. 13.

### <Deposition Apparatus>

An example of a deposition apparatus that can be used in fabrication of a semiconductor device of one embodiment of the present invention is described below.

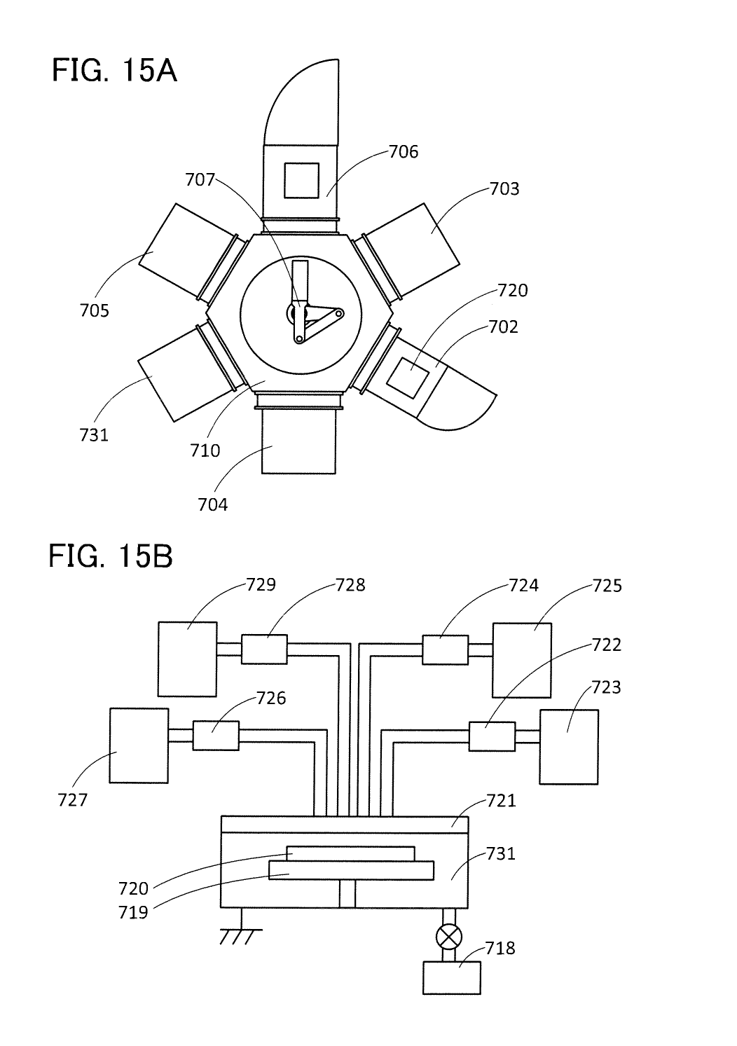

A manufacturing apparatus including a deposition apparatus in FIG. 15A includes at least a load chamber 702, a transfer chamber 710, a treatment chamber 703, a treatment chamber 705, a treatment chamber 731, and an unload chamber 706. In the manufacturing apparatus illustrated in FIG. 15A, a film can be successively formed without exposure to the air. Thus, in the case where a stacked film is formed, entry of impurities into the film and the interface of the film can be prevented. Note that in order to prevent attachment of moisture to the inner wall of the chambers, the chambers of the manufacturing apparatus (including the load chamber, the treatment chamber, the transfer chamber, the deposition chamber, the unload chamber, and the like) are preferably filled with an inert gas (such as a nitrogen gas and a rare gas) whose dew point is lower than −60° C., preferably lower than −80° C., more preferably lower than −100° C. Alternatively, these chambers are set to a reduced pressure state in which the pressure is less than 1 Pa, preferably less than 0.1 Pa, more preferably less than 1×10⁻⁴ Pa.

In at least one of a treatment chamber 704, the treatment chamber 705, and the treatment chamber 731, deposition by a CVD method or an ALD method may be performed. Alternatively, in at least one of the treatment chamber 704, the treatment chamber 705, and the treatment chamber 731, ion implantation or plasma treatment may be performed. Further alternatively, at least one of the treatment chamber 704, the treatment chamber 705, and the treatment chamber 731 may be a heat treatment chamber.

For example, a semiconductor may be deposited in the treatment chamber 731, an insulator may be deposited in the treatment chamber 704, and a conductor may be deposited in the treatment chamber 705. In this case, the semiconductor, the insulator, and the conductor can be successively stacked without exposure to the air.

First, a substrate 720 is transferred to the load chamber 702. Next, the substrate is transferred to the treatment chamber 703 by a transfer unit 707 of the transfer chamber 710. In the treatment chamber 703, treatment for cleaning the surface of the substrate or heat treatment is performed. Then, the substrate is transferred to the treatment chamber 731 and a semiconductor is deposited. By performing the treatment in the treatment chamber 703, the surface of the substrate can be clean. In addition, from the treatment on the surface of the substrate to the deposition of the semiconductor, the substrate is not exposed to the air; thus, attachment of impurities and the like to the surface of the substrate can be inhibited.

Next, the substrate is transferred to the treatment chamber 704 by the transfer unit 707, and an insulator such as hafnium oxide is deposited. Then, the substrate is transferred to the treatment chamber 705 by the transfer unit 707, and a conductor such as tungsten is deposited. Then, the substrate is transferred to the unload chamber 706 by the transfer unit 707. Through the above procedure, the semiconductor, the insulator, and the conductor can be sequentially stacked.

Alternatively, for example, a semiconductor may be deposited in the treatment chamber 731, treatment for adding oxygen may be performed in the treatment chamber 704, and a semiconductor may be deposited in the treatment chamber 705. Further alternatively, for example, a semiconductor may be deposited in the treatment chamber 731, heat treatment may be performed in the treatment chamber 704, and a conductor may be deposited in the treatment chamber 705.

FIG. 15B shows an example of the thermal CVD apparatus. In the thermal CVD apparatus, a film is formed in the following manner: a source gas (one or more kinds), an oxidizer (such as O₂ and O₃), and the like are supplied at the same time to the chamber to which the substrate is transferred; reaction is performed near the substrate or on the surface of the substrate; and reaction products are deposited.

The treatment chamber 731, which is a thermal CVD apparatus, includes at least a substrate holder 719, a member 721 to which introduction ports for the plurality of source gases are connected, and an evacuation unit 718. Source gas introduction ports are each connected to a source material supply portion (a source material supply portion 723, a source material supply portion 725, a source material supply portion 727, or a source material supply portion 729) through a supply tube, a pressure controller, a valve, a mass flow controller (a mass flow controller 722, a mass flow controller 724, a mass flow controller 726, or a mass flow controller 728). A source gas exhaust port is connected to the evacuation unit 718 through an exhaust tube, a valve, and a pressure controller.

The treatment chamber 731 at the time of deposition may be in an atmospheric pressure state or a reduced pressure state.

The source gas may be supplied from a plurality of openings like a shower head.

In order to make the film thickness in a substrate plane uniform, the substrate holder 719 may be rotated to rotate the substrate 720 fixed to the substrate holder 719.

Note that since plasma is not used in a thermal CVD method, defects due to plasma are not generated in the film.

By a thermal CVD method, a variety of films of a metal, a semiconductor, an insulator, and the like can be formed. For example, in the case where an In—Ga—Zn oxide is deposited, as source gases, trimethylindium ((CH₃)₃In), trimethylgallium ((CH₃)₃Ga), and dimethylzinc ((CH₃)₂Zn) are used. However, the source gas of the In—Ga—Zn oxide is not limited to this combination. For example, triethylgallium ((C₂H₅)₃Ga) can be used instead of trimethylgallium and diethylzinc ((C₂H₅)₂Zn) can be used instead of dimethylzinc. In the case where gallium oxide is deposited, for example, trimethylgallium or triethylgallium can be used as a source gas.

Although FIG. 15A shows an example of a multi-chamber manufacturing apparatus in which a top surface shape of the transfer chamber 710 is a hexagon, a manufacturing apparatus in which the top surface shape is a polygon having more than six corners (such as a heptagon and an octagon) and more chambers are connected may be used. Alternatively, a multi-chamber manufacturing apparatus in which a top surface shape of the transfer chamber 710 is a pentagon or a tetragon may be used. Alternatively, an in-line manufacturing apparatus in which the transfer chamber is omitted by connecting a plurality of chambers to each other may be used. The in-line manufacturing apparatus has high productivity because it includes a smaller number of transfer chambers and the transfer time can be shortened. Although FIG. 15A shows an example of the single wafer manufacturing apparatus, a batch-type deposition apparatus in which films are deposited over a plurality of substrates at a time may be used. In addition, a mechanism for cleaning (such as plasma cleaning) may be included in each treatment chamber.

Although FIG. 15B shows an example in which a thermal CVD apparatus is used as each of the treatment chamber 704, the treatment chamber 705, and the treatment chamber 731, in any one of these treatment chambers, deposition by another deposition method such as a sputtering method or an ALD method may be performed.

### <Semiconductor Device>

An example of a semiconductor device of one embodiment of the present invention is shown below.

### <Circuit>

An example of a circuit including a transistor of one embodiment of the present invention is shown below.

### [CMOS Inverter]

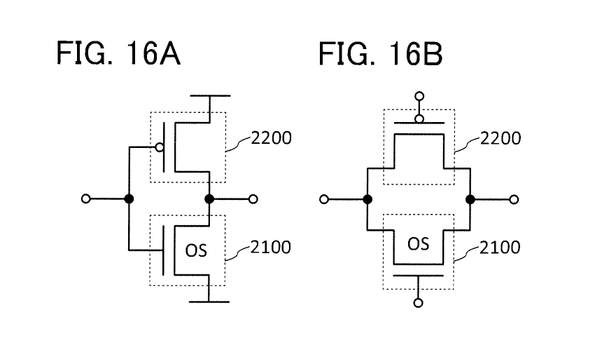

A circuit diagram in FIG. 16A shows a configuration of a so-called CMOS inverter in which the p-channel transistor 2200 and the n-channel transistor 2100 are connected to each other in series and in which gates of them are connected to each other.

### [CMOS Analog Switch]

A circuit diagram in FIG. 16B shows a configuration in which sources of the transistors 2100 and 2200 are connected to each other and drains of the transistors 2100 and 2200 are connected to each other. With such a configuration, the transistors can function as a so-called CMOS analog switch.

### [Memory Device Example]

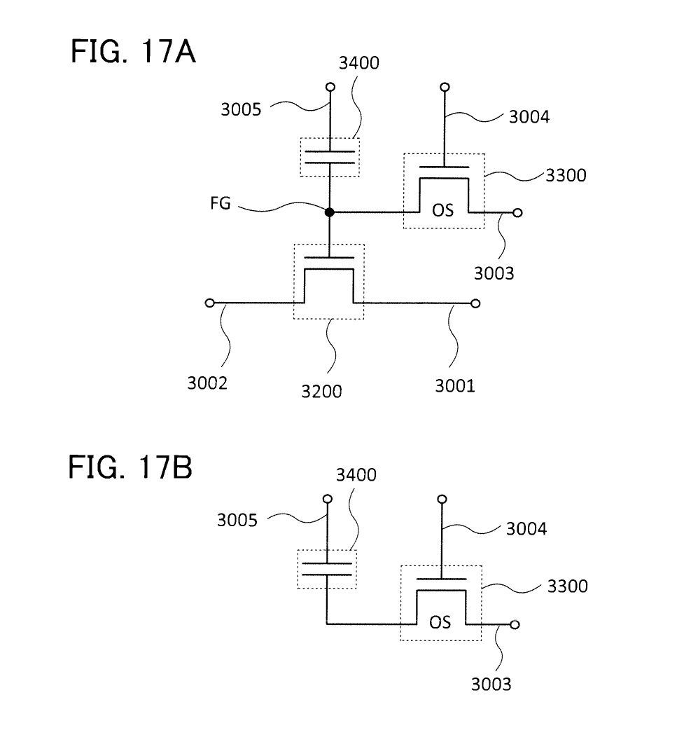

An example of a semiconductor device (memory device) which includes the transistor of one embodiment of the present invention, which can retain stored data even when not powered, and which has an unlimited number of write cycles is shown in FIGS. 17A and 17B.

The semiconductor device illustrated in FIG. 17A includes a transistor 3200 using a first semiconductor, a transistor 3300 using a second semiconductor, and a capacitor 3400. Note that any of the above-described transistors can be used as the transistor 3300.

The transistor 3300 is a transistor using an oxide semiconductor. Since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 17A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to one electrode of the capacitor 3400. A fifth wiring 3005 is electrically connected to the other electrode of the capacitor 3400.

The semiconductor device in FIG. 17A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge is held at the node FG (retaining).

Since the off-state current of the transistor 3300 is extremely low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is turned on. By contrast, in the case where the low-level charge is supplied to the node FG, even when the potential of the fifth wiring 3005 is V₀ (<Vₜₕ_{_{—}}_{L}), the transistor 3200 remains off. Thus, the data retained in the node FG can be read by determining the potential of the second wiring 3002.

Note that in the case where memory cells are arrayed, it is necessary that data of a desired memory cell be read in read operation. In the case where data of the other memory cells is not read, the fifth wiring 3005 may be supplied with a potential at which the transistor 3200 is turned off regardless of the charge supplied to the node FG, that is, a potential lower than Vₜₕ_{_{—}}_{H}. Alternatively, the fifth wiring 3005 may be supplied with a potential at which the transistor 3200 is turned on regardless of the charge supplied to the node FG, that is, a potential higher than Vₜₕ_{_{—}}_{L}.

The semiconductor device in FIG. 17B is different form the semiconductor device in FIG. 17A in that the transistor 3200 is not provided. Also in this case, writing and retaining operation of data can be performed in a manner similar to that of the semiconductor device in FIG. 17A.

Reading of data in the semiconductor device in FIG. 17B is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When including a transistor using an oxide semiconductor and having an extremely low off-state current, the semiconductor device described above can retain stored data for a long time. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

Further, in the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the state of the transistor (on or off), whereby high-speed operation can be easily achieved.

### <RF Tag>

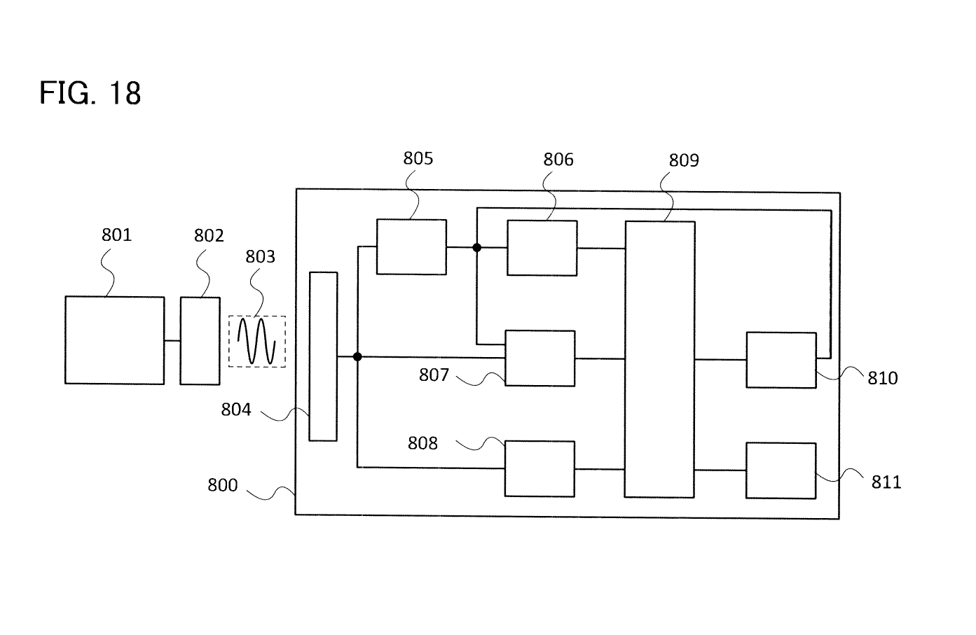

An RF tag including the transistor or the memory device is described below with reference to FIG. 18.

The RF tag of one embodiment of the present invention includes a memory circuit, stores data in the memory circuit, and transmits and receives data to/from the outside by using contactless means, for example, wireless communication. With these features, the RF tag can be used for an individual authentication system in which an object or the like is recognized by reading the individual information, for example. Note that the RF tag is required to have high reliability in order to be used for this purpose.

A configuration of the RF tag will be described with reference to FIG. 18. FIG. 18 is a block diagram illustrating a configuration example of an RF tag.

As shown in FIG. 18, an RF tag 800 includes an antenna 804 which receives a radio signal 803 that is transmitted from an antenna 802 connected to a communication device 801 (also referred to as an interrogator, a reader/writer, or the like). The RF tag 800 includes a rectifier circuit 805, a constant voltage circuit 806, a demodulation circuit 807, a modulation circuit 808, a logic circuit 809, a memory circuit 810, and a ROM 811. A semiconductor of a transistor having a rectifying function included in the demodulation circuit 807 may be a material which enables a reverse current to be low enough, for example, an oxide semiconductor. This can suppress the phenomenon of a rectifying function becoming weaker due to generation of a reverse current and prevent saturation of the output from the demodulation circuit. In other words, the input to the demodulation circuit and the output from the demodulation circuit can have a relation closer to a linear relation. Note that data transmission methods are roughly classified into the following three methods: an electromagnetic coupling method in which a pair of coils is provided so as to face each other and communicates with each other by mutual induction, an electromagnetic induction method in which communication is performed using an induction field, and a radio wave method in which communication is performed using a radio wave. Any of these methods can be used in the RF tag 800.

Next, the structure of each circuit will be described. The antenna 804 exchanges the radio signal 803 with the antenna 802 which is connected to the communication device 801. The rectifier circuit 805 generates an input potential by rectification, for example, half-wave voltage doubler rectification of an input alternating signal generated by reception of a radio signal at the antenna 804 and smoothing of the rectified signal with a capacitor provided in a later stage in the rectifier circuit 805. Note that a limiter circuit may be provided on an input side or an output side of the rectifier circuit 805. The limiter circuit controls electric power so that electric power which is higher than or equal to certain electric power is not input to a circuit in a later stage if the amplitude of the input alternating signal is high and an internal generation voltage is high.

The constant voltage circuit 806 generates a stable power supply voltage from an input potential and supplies it to each circuit. Note that the constant voltage circuit 806 may include a reset signal generation circuit. The reset signal generation circuit is a circuit which generates a reset signal of the logic circuit 809 by utilizing rise of the stable power supply voltage.

The demodulation circuit 807 demodulates the input alternating signal by envelope detection and generates the demodulated signal. Further, the modulation circuit 808 performs modulation in accordance with data to be output from the antenna 804.

The logic circuit 809 analyzes and processes the demodulated signal. The memory circuit 810 holds the input data and includes a row decoder, a column decoder, a memory region, and the like. Further, the ROM 811 stores an identification number (ID) or the like and outputs it in accordance with processing.

Note that the decision whether each circuit described above is provided or not can be made as appropriate.

Here, the above-described memory device can be used as the memory circuit 810. Since the memory device of one embodiment of the present invention can retain data even when not powered, the memory device is suitable for an RF tag. Further, the memory device of one embodiment of the present invention needs power (voltage) needed for data writing lower than that needed in a conventional nonvolatile memory; thus, it is possible to prevent a difference between the maximum communication range in data reading and that in data writing. Furthermore, it is possible to suppress malfunction or incorrect writing which is caused by power shortage in data writing.

Since the memory device of one embodiment of the present invention can be used as a nonvolatile memory, it can also be used as the ROM 811. In this case, it is preferable that a manufacturer separately prepare a command for writing data to the ROM 811 so that a user cannot rewrite data freely. Since the manufacturer gives identification numbers before shipment and then starts shipment of products, instead of putting identification numbers to all the manufactured RF tags, it is possible to put identification numbers to only good products to be shipped. Thus, the identification numbers of the shipped products are in series and customer management corresponding to the shipped products is easily performed.

### <Application Examples of RF Tag>

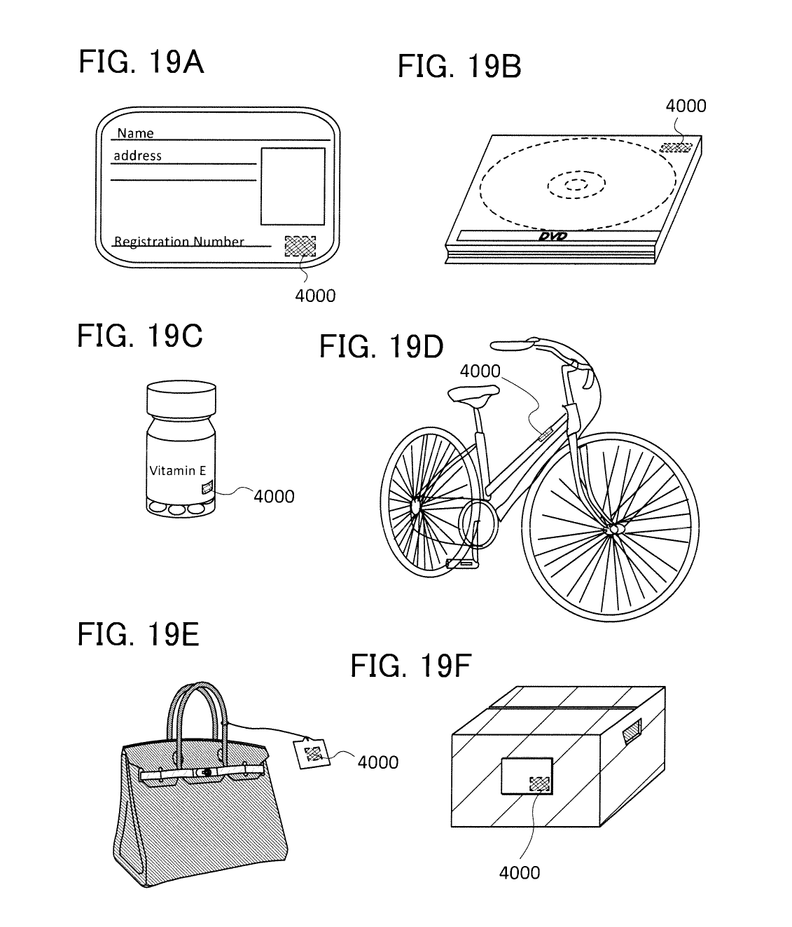

Application examples of the RF tag of one embodiment of the present invention are described below with reference to FIGS. 19A to 19F. The RF tag is widely used and can be provided for, for example, products such as bills, coins, securities, bearer bonds, documents (e.g., driver's licenses or resident's cards, see FIG. 19A), packaging containers (e.g., wrapping paper or bottles, see FIG. 19C), recording media (e.g., DVD or video tapes, see FIG. 19B), vehicles (e.g., bicycles, see FIG. 19D), personal belongings (e.g., bags or glasses), foods, plants, animals, human bodies, clothing, household goods, medical supplies such as medicine and chemicals, and electronic devices (e.g., liquid crystal display devices, EL display devices, television sets, or mobile phones), or tags on products (see FIGS. 19E and 19F).

An RF tag 4000 of one embodiment of the present invention is fixed on products by, for example, being attached to a surface thereof or being embedded therein. For example, the RF tag 4000 is fixed to each product by being embedded in paper of a book, or embedded in an organic resin of a package. The RF tag 4000 of one embodiment of the present invention is small, thin, and lightweight, so that the design of a product is not impaired even after the RF tag 4000 of one embodiment of the present invention is fixed thereto. Further, bills, coins, securities, bearer bonds, documents, or the like can have identification functions by being provided with the RF tag 4000 of one embodiment of the present invention, and the identification functions can be utilized to prevent counterfeits. Moreover, the efficiency of a system such as an inspection system can be improved by providing the RF tag 4000 of one embodiment of the present invention for packaging containers, recording media, personal belongings, foods, clothing, household goods, electronic devices, or the like. Vehicles can also have higher security against theft or the like by being provided with the RF tag 4000 of one embodiment of the present invention.

As described above, the RF tag of one embodiment of the present invention can be used for the above-described purposes.

### <CPU>

A CPU including a semiconductor device such as any of the above-described transistors or the above-described memory device is described below.

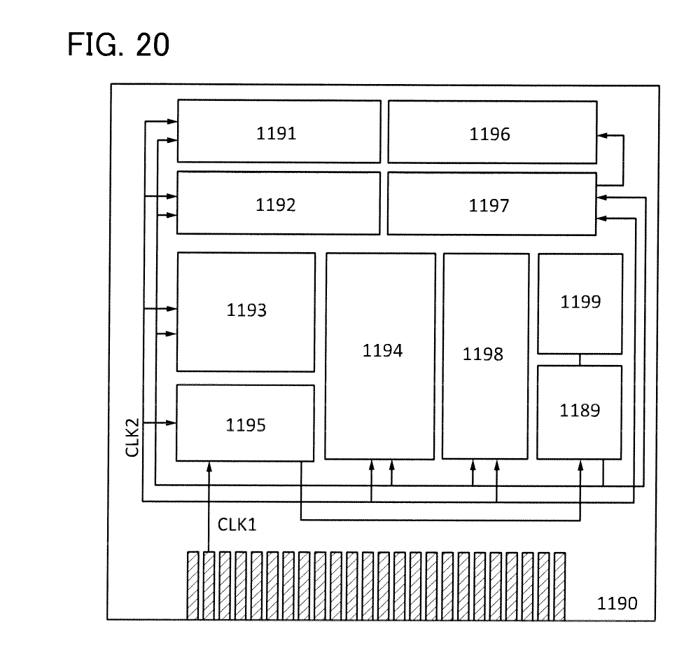

FIG. 20 is a block diagram illustrating a configuration example of a CPU including any of the above-described transistors as a component.

The CPU illustrated in FIG. 20 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and an ROM interface 1189. A semiconductor substrate, an SOI substrate, a glass substrate, or the like is used as the substrate 1190. The rewritable ROM 1199 and the ROM interface 1189 may be provided over a separate chip. Needless to say, the CPU in FIG. 20 is just an example in which the configuration has been simplified, and an actual CPU may have a variety of configurations depending on the application. For example, the CPU may have the following configuration: a structure including the CPU illustrated in FIG. 20 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

In the CPU illustrated in FIG. 20, a memory cell is provided in the register 1196. For the memory cell of the register 1196, any of the above-described transistors, the above-described memory device, or the like can be used.

In the CPU illustrated in FIG. 20, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

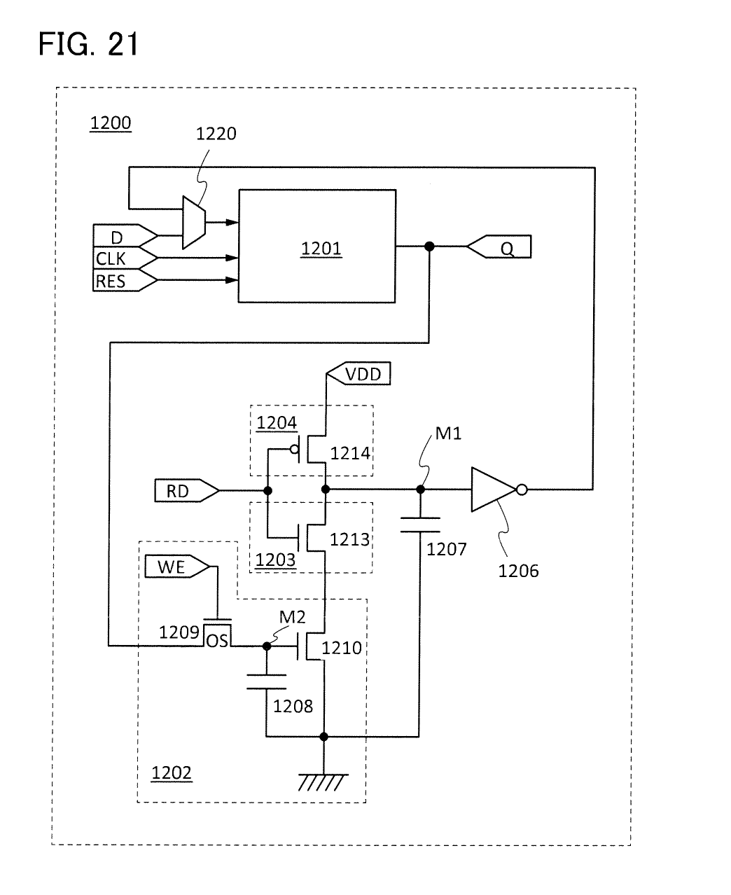

FIG. 21 is an example of a circuit diagram of a memory element 1200 that can be used as the register 1196. The memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the gate of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 21 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 21, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 21, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor. Further alternatively, in the memory element 1200, a transistor in which a channel is formed in an oxide semiconductor can be included besides the transistor 1209, and a transistor in which a channel is formed in a layer including a semiconductor other than an oxide semiconductor or in the substrate 1190 can be used for the rest of the transistors.

As the circuit 1201 in FIG. 21, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### Configuration Example

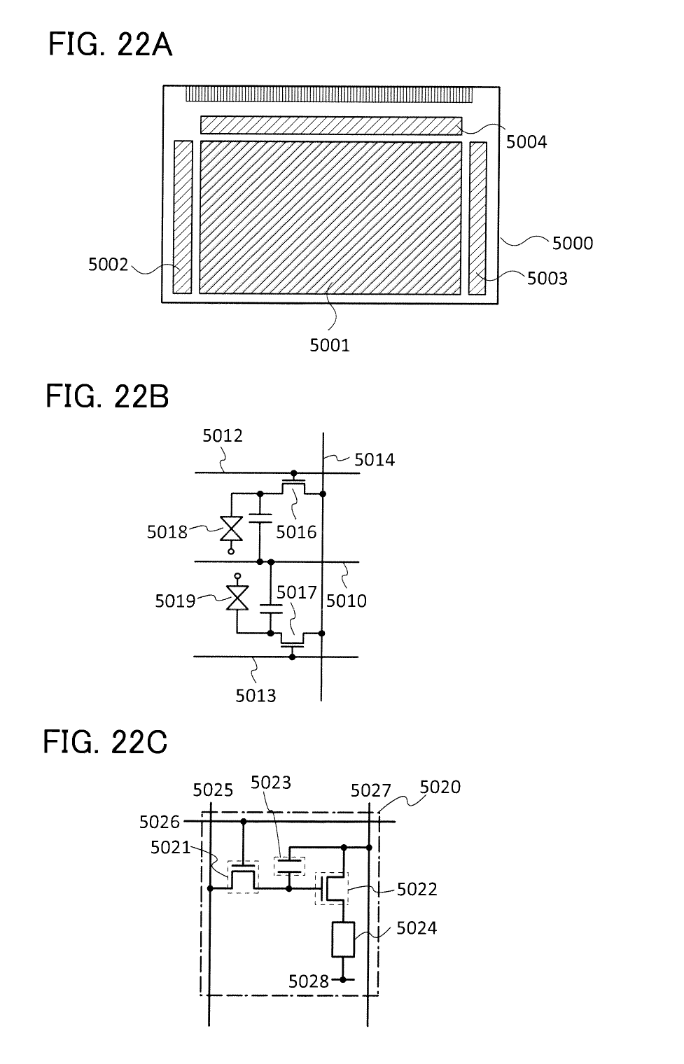

FIG. 22A is a top view of a display device of one embodiment of the present invention. FIG. 22B illustrates a pixel circuit where a liquid crystal element is used for a pixel of a display device of one embodiment of the present invention. FIG. 22C illustrates a pixel circuit where an organic EL element is used for a pixel of a display device of one embodiment of the present invention.

Any of the above-described transistors can be used as a transistor used for the pixel. Here, an example in which an n-channel transistor is used is shown. Note that a transistor manufactured through the same steps as the transistor used for the pixel may be used for a driver circuit. Thus, by using any of the above-described transistors for a pixel or a driver circuit, the display device can have high display quality and/or high reliability.

FIG. 22A illustrates an example of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Further, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 22B illustrates an example of a circuit configuration of the pixel. Here, a pixel circuit which is applicable to a pixel of a VA liquid crystal display device, or the like is illustrated.

This pixel circuit can be applied to a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A scan line 5012 of a transistor 5016 and a scan line 5013 of a transistor 5017 are separated so that different gate signals can be supplied thereto. By contrast, a signal line 5014 is shared by the transistors 5016 and 5017. Any of the above-described transistors can be used as appropriate as each of the transistors 5016 and 5017. Thus, the liquid crystal display device can have high display quality and/or high reliability.

A first pixel electrode is electrically connected to the transistor 5016 and a second pixel electrode is electrically connected to the transistor 5017. The first pixel electrode and the second pixel electrode are separated. Shapes of the first pixel electrode and the second pixel electrode are not especially limited, and for example, the first pixel electrode may have a V-like shape.

A gate electrode of the transistor 5016 is electrically connected to the scan line 5012, and a gate electrode of the transistor 5017 is electrically connected to the scan line 5013. When different gate signals are supplied to the scan line 5012 and the scan line 5013, operation timings of the transistor 5016 and the transistor 5017 can be varied. As a result, alignment of liquid crystals can be controlled.

Further, a capacitor may be formed using a capacitor line 5010, a gate insulator functioning as a dielectric, and a capacitor electrode electrically connected to the first pixel electrode or the second pixel electrode.

The pixel structure is a multi-domain structure in which a first liquid crystal element 5018 and a second liquid crystal element 5019 are provided in one pixel. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 22B. For example, a switch, a resistor, a capacitor, a transistor, a sensor, a logic circuit, or the like may be added to the pixel circuit shown in FIG. 22B.

### [Organic EL Panel]

FIG. 22C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, a current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 22C illustrates an example of a pixel circuit. Here, one pixel includes two n-channel transistors. Note that any of the above-described transistors can be used as the n-channel transistors. Further, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, any of the above-described transistors can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby a current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that a current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply a current to the light-emitting element 5024 in accordance with the video signal and perform analog grayscale driving.

Note that in the display device of one embodiment of the present invention, a pixel configuration is not limited to that shown in FIG. 22C. For example, a switch, a resistor, a capacitor, a sensor, a transistor, a logic circuit, or the like may be added to the pixel circuit shown in FIG. 22C.

In the case where any of the above-described transistors is used for the circuit shown in FIGS. 22A to 22C, the source electrode (the first electrode) is electrically connected to the low potential side and the drain electrode (the second electrode) is electrically connected to the high potential side. Further, the potential of the first gate electrode may be controlled by a control circuit or the like and the potential described above as an example, e.g., a potential lower than the potential applied to the source electrode, may be input to the second gate electrode.

### <Module>

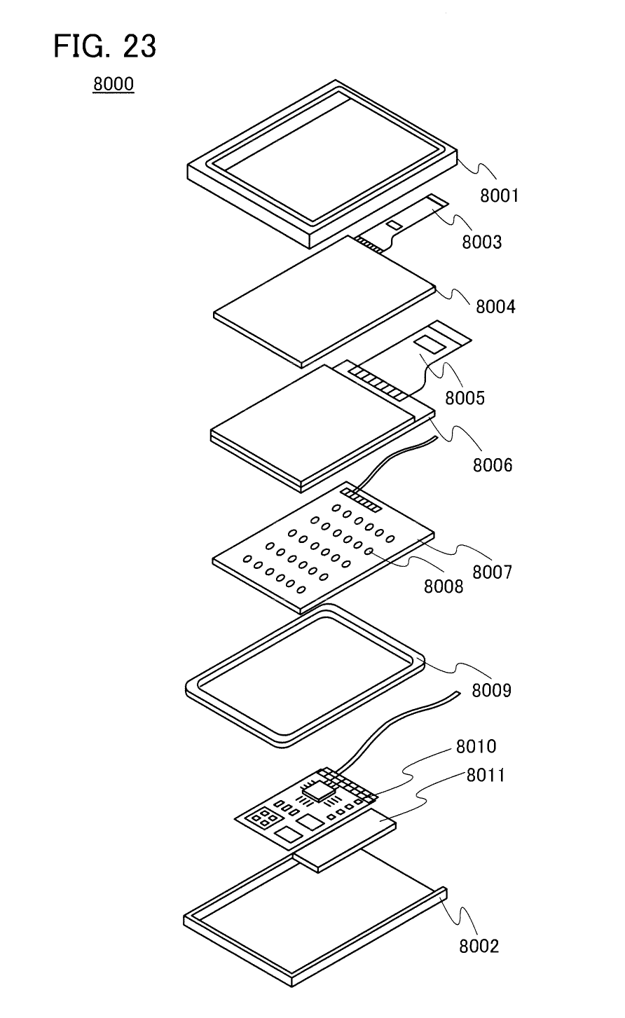

A display module using a semiconductor device of one embodiment of the present invention is described below with reference to FIG. 23.

In a display module 8000 in FIG. 23, a touch panel 8004 connected to an FPC 8003, a cell 8006 connected to an FPC 8005, a backlight unit 8007, a frame 8009, a printed circuit board 8010, and a battery 8011 are provided between an upper cover 8001 and a lower cover 8002. Note that the backlight unit 8007, the battery 8011, the touch panel 8004, and the like are not provided in some cases.

The semiconductor device of one embodiment of the present invention can be used for the cell 8006, for example.

The shapes and sizes of the upper cover 8001 and the lower cover 8002 can be changed as appropriate in accordance with the sizes of the touch panel 8004 and the cell 8006.

The touch panel 8004 can be a resistive touch panel or a capacitive touch panel and may be formed to overlap with the cell 8006. A counter substrate (sealing substrate) of the cell 8006 can have a touch panel function. A photosensor may be provided in each pixel of the cell 8006 so that an optical touch panel is obtained.

The backlight unit 8007 includes a light source 8008. The light source 8008 may be provided at an end portion of the backlight unit 8007 and a light diffusing plate may be used.

The frame 8009 may protect the cell 8006 and also function as an electromagnetic shield for blocking electromagnetic waves generated by the operation of the printed circuit board 8010. The frame 8009 may function as a radiator plate.

The printed circuit board 8010 has a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 can be additionally provided with a member such as a polarizing plate, a retardation plate, or a prism sheet.

### <Electronic Device>

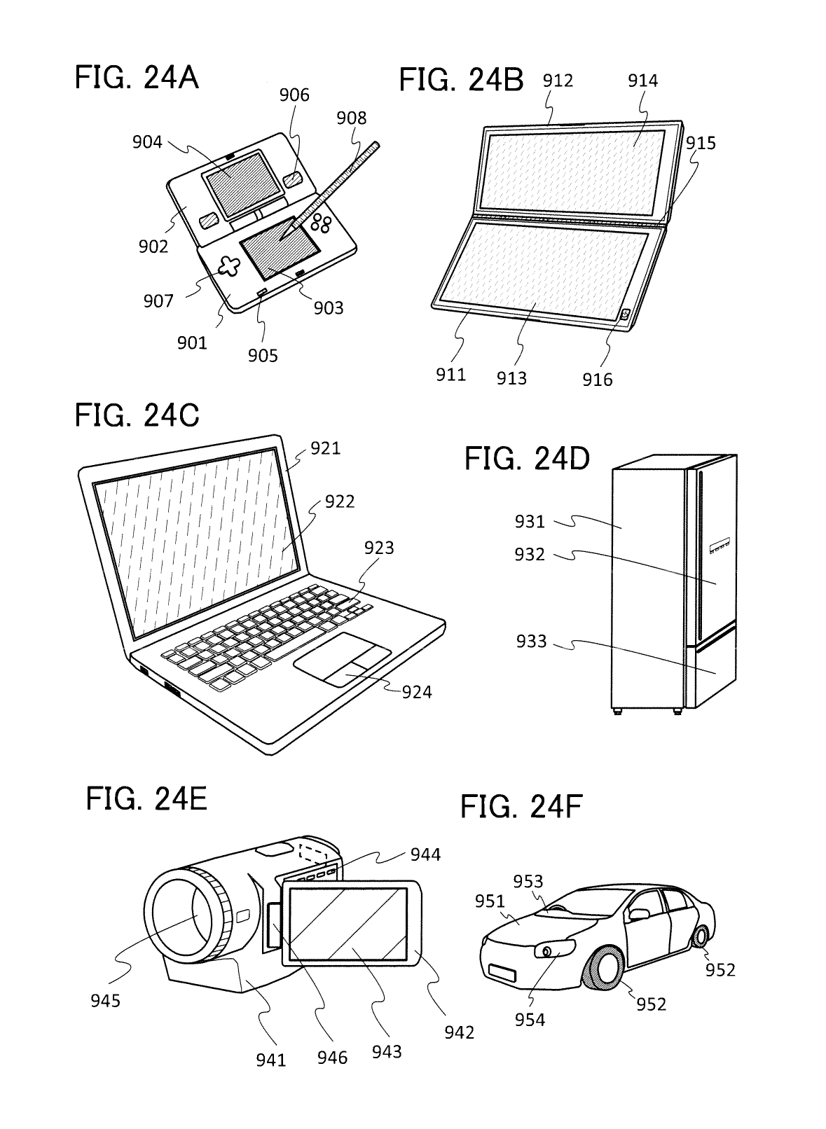

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game machines, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 24A to 24F illustrate specific examples of these electronic devices.

FIG. 24A illustrates a portable game machine including a housing 901, a housing 902, a display portion 903, a display portion 904, a microphone 905, a speaker 906, an operation key 907, a stylus 908, and the like. Although the portable game machine in FIG. 24A has the two display portions 903 and 904, the number of display portions included in a portable game machine is not limited to this.

FIG. 24B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched depending on the angle between the first housing 911 and the second housing 912 at the joint 915. A display device with a position input function may be used as at least one of the first display portion 913 and the second display portion 914. Note that the position input function can be added by providing a touch panel in a display device. Alternatively, the position input function can be added by provision of a photoelectric conversion element called a photosensor in a pixel portion of a display device.

FIG. 24C illustrates a laptop personal computer, which includes a housing 921, a display portion 922, a keyboard 923, a pointing device 924, and the like.

FIG. 24D illustrates the electric refrigerator-freezer including a housing 931, a door for a refrigerator 932, a door for a freezer 933, and the like.

FIG. 24E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 24F illustrates an ordinary vehicle including a car body 951, wheels 952, a dashboard 953, lights 954, and the like.

<Electronic Device with Curved Display Region or Curved Light-Emitting Region>

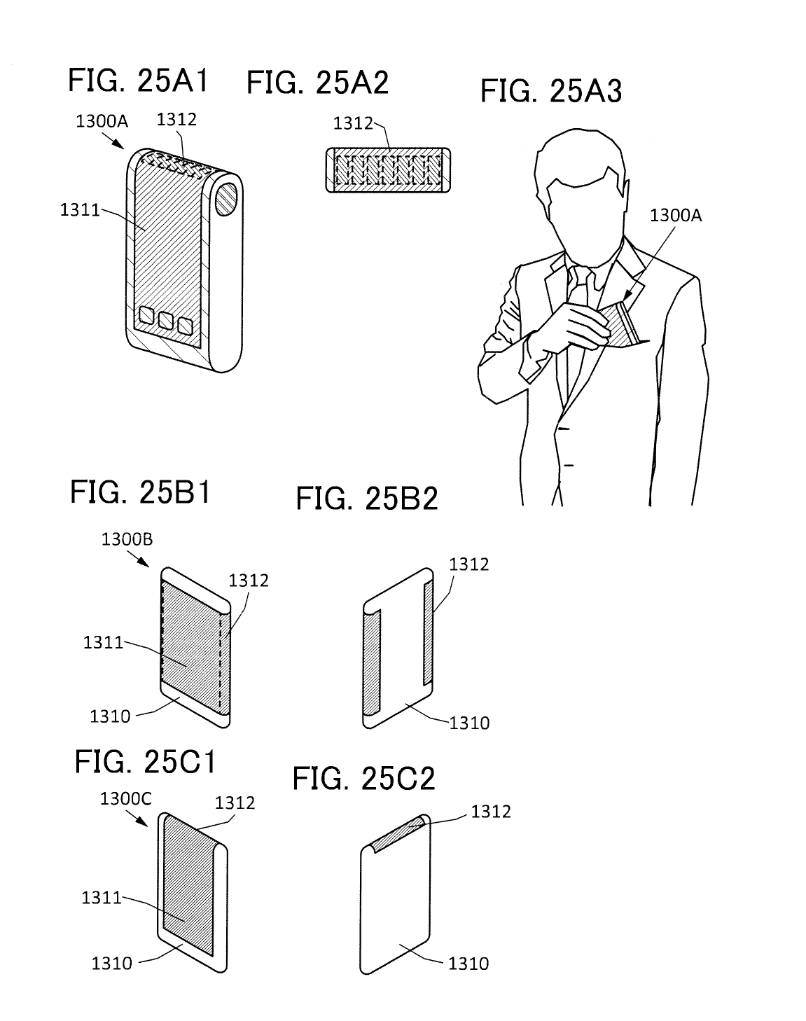

Electronic devices with a curved display region or a curved light-emitting region, which are embodiments of the present invention, are described below with reference to FIGS. 25A1, 25A2, 25A3, 25B1, 25B2, 25C1, and 25C2. Here, information devices, in particular, portable information devices (portable devices) are described as examples of the electronic devices. The portable information devices include, for example, mobile phone devices (e.g., phablets and smartphones) and tablet terminals (slate PCs).

FIG. 25A1 is a perspective view illustrating an external shape of a portable device 1300A. FIG. 25A2 is a top view illustrating the portable device 1300A. FIG. 25A3 illustrates a usage state of the portable device 1300A.

FIGS. 25B1 and 25B2 are perspective views illustrating the outward form of a portable device 1300B.

FIGS. 25C1 and 25C2 are perspective views illustrating the outward form of a portable device 1300C.

### <Portable Device>

The portable device 1300A has one or more functions of a telephone, email creating and reading, a notebook, information browsing, and the like.

A display portion of the portable device 1300A is provided along plural surfaces. For example, the display portion may be provided by placing a flexible display device along the inside of a housing. Thus, text data, image data, or the like can be displayed on a first region 1311 and/or a second region 1312.

For example, images used for three operations can be displayed on the first region 1311 (see FIG. 25A1). Furthermore, text data and the like can be displayed on the second region 1312 as indicated by dashed rectangles in the drawing (see FIG. 25A2).

In the case where the second region 1312 is on the upper portion of the portable device 1300A, a user can easily see text data or image data displayed on the second region 1312 of the portable device 1300A while the portable device 1300A is placed in a breast pocket of the user's clothes (see FIG. 25A3). For example, the user can see the phone number, name, and the like of the caller of an incoming call, from above the portable device 1300A.

The portable device 1300A may include an input device or the like between the display device and the housing, in the display device, or over the housing. As the input device, for example, a touch sensor, an optical sensor, or an ultrasonic sensor may be used. In the case where the input device is provided between the display device and the housing or over the housing, a touch panel may be, for example, a matrix switch type, a resistive type, an ultrasonic surface acoustic wave type, an infrared type, electromagnetic induction type, or an electrostatic capacitance type. In the case where the input device is provided in the display device, an in-cell sensor, an on-cell sensor, or the like may be used.

Note that the portable device 1300A can be provided with a vibration sensor or the like and a memory device that stores a program for shifting a mode into an incoming call rejection mode based on vibration sensed by the vibration sensor or the like. Thus, the user can shift the mode into the incoming call rejection mode by tapping the portable device 1300A over his/her clothes to apply vibration.

The portable device 1300B includes a display portion including the first region 1311 and the second region 1312 and a housing 1310 that supports the display portion.

The housing 1310 has a plurality of bend portions, and the longest bend portion in the housing 1310 is between the first region 1311 and the second region 1312.

The portable device 1300B can be used with the second region 1312 provided along the longest bend portion facing sideward.

The portable device 1300C includes a display portion including the first region 1311 and the second region 1312 and the housing 1310 that supports the display portion.

The housing 1310 has a plurality of bend portions, and the second longest bend portion in the housing 1310 is between the first region 1311 and the second region 1312.

The portable device 1300C can be used with the second region 1312 facing upward.

Note that what is described in an embodiment can be applied to, combined with, or exchanged with another content in the same embodiment.

Note that a content described in an embodiment is a content described with reference to a variety of diagrams or a content described with a text disclosed in this specification.

Note that by combining a diagram (or part thereof) described in an embodiment with another part of the diagram or a different diagram (or part thereof) described in the same embodiment, much more diagrams can be formed.

Note that contents that are not specified in any drawing or text can be excluded from one embodiment of the invention. Alternatively, when the range of a value (e.g., the maximum and minimum values) is described, the range may be freely narrowed or a value in the range may be excluded, so that one embodiment of the invention can be specified by a range part of which is excluded. In this manner, it is possible to specify the technical scope of one embodiment of the present invention so that a conventional technology is excluded, for example.

As a specific example, a diagram of a circuit including a first transistor to a fifth transistor is illustrated. In that case, it can be specified that the circuit does not include a sixth transistor in the invention. It can be specified that the circuit does not include a capacitor in the invention. It can be specified that the circuit does not include a sixth transistor with a particular connection structure in the invention. It can be specified that the circuit does not include a capacitor with a particular connection structure in the invention. For example, it can be specified that a sixth transistor whose gate is connected to a gate of the third transistor is not included in the invention. For example, it can be specified that a capacitor whose first electrode is connected to the gate of the third transistor is not included in the invention.

As another specific example, a case in which a description of a value, “a voltage is preferably higher than or equal to 3 V and lower than or equal to 10 V” is provided is considered. In that case, for example, it can be specified that the case where the voltage is higher than or equal to −2 V and lower than or equal to 1 V is excluded from one embodiment of the invention. For example, it can be specified that the case where the voltage is higher than or equal to 13 V is excluded from one embodiment of the invention. Note that for example, it can be specified that the voltage is higher than or equal to 5 V and lower than or equal to 8 V in the invention. Note that for example, it can be specified that in an invention, the voltage is approximately 9 V. For example, it can be specified that the voltage is higher than or equal to 3 V and lower than or equal to 10 V but is not 9 V in the invention. Note that even when the description “a value is preferably in a certain range” or “a value preferably satisfies a certain condition” is given, the value is not limited to the description. In other words, a description of a value that includes a term “preferable”, “preferably”, or the like does not necessarily limit the value.

As another specific example, the description “a voltage is preferred to be 10 V” is given. In that case, for example, it can be specified that the case where the voltage is higher than or equal to −2 V and lower than or equal to 1 V is excluded from one embodiment of the invention. For example, it can be specified that the case where the voltage is higher than or equal to 13 V is excluded from one embodiment of the invention.

As another specific example, the description “something is an insulator” is given to describe a property of a material. In that case, for example, it can be specified that the case where something is an organic insulator is excluded from one embodiment of the invention. For example, it can be specified that the case where something is an inorganic insulator is excluded from one embodiment of the invention. For example, it can be specified that the case where something is a conductor is excluded from one embodiment of the invention. For example, it can be specified that the case where something is a semiconductor is excluded from one embodiment of the invention.

As another specific example, the description of a stacked structure, “a film is provided between film A and film B” is given. In that case, for example, it can be specified that the case where the film is a layered film of four or more layers is excluded from one embodiment of the invention. For example, it can be specified that the case where a conductor is provided between film A and the film is excluded from one embodiment of the invention.

Note that in this specification and the like, it may be possible for those skilled in the art to constitute one embodiment of the invention even when portions to which all the terminals of an active element (e.g., a transistor or a diode), a passive element (e.g., a capacitor or a resistor), or the like are connected are not specified. In other words, one embodiment of the invention is clear even when connection portions are not specified. Further, in the case where a connection portion is disclosed in this specification and the like, it can be determined that one embodiment of the invention in which a connection portion is not specified is disclosed in this specification and the like, in some cases. In particular, in the case where the number of portions to which the terminal is connected may be more than one, it is not necessary to specify the portions to which the terminal is connected. Therefore, it may be possible to constitute one embodiment of the invention by specifying only portions to which some of terminals of an active element (e.g., a transistor or a diode), a passive element (e.g., a capacitor or a resistor), and the like are connected.

Note that in this specification and the like, it may be possible for those skilled in the art to specify the invention when at least the connection portion of a circuit is specified. Alternatively, it may be possible for those skilled in the art to specify the invention when at least a function of a circuit is specified. In other words, when a function of a circuit is specified, one embodiment of the present invention is clear, and it can be determined that the embodiment is disclosed in this specification and the like. Therefore, when a connection portion of a circuit is specified, the circuit is disclosed as one embodiment of the invention even when a function is not specified, and one embodiment of the invention can be constituted. Alternatively, when a function of a circuit is specified, the circuit is disclosed as one embodiment of the invention even when a connection portion is not specified, and one embodiment of the invention can be constituted.

Note that in this specification and the like, part of a diagram or text described in one embodiment can be taken out to constitute one embodiment of the invention. Thus, in the case where a diagram or text related to a certain portion is described, the contents taken out from part of the diagram or the text are also disclosed as one embodiment of the invention, and one embodiment of the invention can be constituted. The embodiment of the present invention is clear. Therefore, for example, in a diagram or text in which one or more active elements (e.g., transistors or diodes), wirings, passive elements (e.g., capacitors or resistors), conductive layers, insulating layers, semiconductor layers, organic materials, inorganic materials, components, devices, operating methods, manufacturing methods, or the like are described, part of the diagram or the text is taken out, and one embodiment of the invention can be constituted. For example, from a circuit diagram in which N circuit elements (e.g., transistors or capacitors; N is an integer) are provided, it is possible to take out M circuit elements (e.g., transistors or capacitors; M is an integer, where M<N) and constitute one embodiment of the invention. For another example, it is possible to take out M layers (M is an integer, where M<N) from a cross-sectional view in which N layers (N is an integer) are provided and constitute one embodiment of the invention. For another example, it is possible to take out M elements (M is an integer, where M<N) from a flow chart in which N elements (N is an integer) are provided and constitute one embodiment of the invention. For another example, it is possible to take out some given elements from a sentence “A includes B, C, D, E, or F” and constitute one embodiment of the invention, for example, “A includes B and E”, “A includes E and F”, “A includes C, E, and F”, or “A includes B, C, D, and E”.

Note that in the case where at least one specific example is described in a diagram or text described in one embodiment in this specification and the like, it will be readily appreciated by those skilled in the art that a broader concept of the specific example can be derived. Therefore, in the diagram or the text described in one embodiment, in the case where at least one specific example is described, a broader concept of the specific example is disclosed as one embodiment of the invention, and one embodiment of the invention can be constituted. The embodiment of the present invention is clear.

Note that in this specification and the like, what is illustrated in at least a diagram (which may be part of the diagram) is disclosed as one embodiment of the invention, and one embodiment of the invention can be constituted. Therefore, when certain contents are described in a diagram, the contents are disclosed as one embodiment of the invention even when the contents are not described with text, and one embodiment of the invention can be constituted. In a similar manner, part of a diagram, which is taken out from the diagram, is disclosed as one embodiment of the invention, and one embodiment of the invention can be constituted. The embodiment of the present invention is clear.

This application is based on Japanese Patent Application serial no. 2014-051720 filed with Japan Patent Office on Mar. 14, 2014, the entire contents of which are hereby incorporated by reference.

What is claimed is:

1. A method for manufacturing a semiconductor device, comprising:
a first step of forming a first conductor over a substrate by a CVD method;
a second step of processing the first conductor after the first step to form a second conductor;
a third step of forming a first insulator over the second conductor after the second step by a CVD method;
a fourth step of forming a first semiconductor over the first insulator after the third step by a CVD method;
a fifth step of forming a second semiconductor over the first semiconductor after the fourth step by a CVD method;
a sixth step of processing the second semiconductor after the fifth step to form a third semiconductor;
a seventh step of processing the first semiconductor after the sixth step to form a fourth semiconductor;
an eighth step of forming a third conductor over the third semiconductor after the seventh step by a CVD method;
a ninth step of processing the third conductor after the eighth step to form a fourth conductor and a fifth conductor and expose the third semiconductor;
a tenth step of forming a fifth semiconductor over the third semiconductor, the fourth conductor, and the fifth conductor after the ninth step by a CVD method;
an eleventh step of forming a second insulator over the fifth semiconductor after the tenth step by a CVD method;
a twelfth step of forming a sixth conductor over the second insulator after the eleventh step by a CVD method;
a thirteenth step of processing the sixth conductor after the twelfth step to form a seventh conductor;
a fourteenth step of processing the second insulator after the thirteenth step to form a third insulator; and
a fifteenth step of processing the fifth semiconductor after the fourteenth step to form a sixth semiconductor,
wherein exposure to air does not occur between the third step and the fourth step, and
wherein exposure to air does not occur between the tenth step and the eleventh step.

2. The method for manufacturing the semiconductor device according to claim 1, wherein exposure to air does not occur between the fourth step and the fifth step.

3. The method for manufacturing the semiconductor device according to claim 1, wherein heat treatment is performed after the fifth step.

4. The method for manufacturing the semiconductor device according to claim 1, further comprising, before the first step, a step of forming a fourth insulator with a function of blocking hydrogen by a CVD method.

5. The method for manufacturing the semiconductor device according to claim 1, further comprising, after the fifteenth step, a step of forming a fifth insulator with a function of blocking hydrogen by a CVD method.

6. The method for manufacturing the semiconductor device according to claim 1, further comprising, after the fourth step, a step of adding oxygen to the first semiconductor.

7. A method for manufacturing a semiconductor device, comprising:
a first step of forming a first conductor over a substrate by a CVD method;
a second step of processing the first conductor after the first step to form a second conductor;
a third step of forming a first insulator over the second conductor after the second step by a CVD method;
a fourth step of forming a first semiconductor over the first insulator after the third step by a CVD method;
a fifth step of forming a second semiconductor over the first semiconductor after the fourth step by a CVD method;
a sixth step of forming a third conductor over the second semiconductor after the fifth step by a CVD method;
a seventh step of processing the third conductor after the sixth step to form a fourth conductor;
an eighth step of processing the second semiconductor after the seventh step to form a third semiconductor;
a ninth step of processing the first semiconductor after the eighth step to form a fourth semiconductor;
a tenth step of processing the fourth conductor after the ninth step to form a fifth conductor and a sixth conductor and expose the third semiconductor;
an eleventh step of forming a fifth semiconductor over the third semiconductor, the fifth conductor, and the sixth conductor after the tenth step by a CVD method;
a twelfth step of forming a second insulator over the fifth semiconductor after the eleventh step by a CVD method;
a thirteenth step of forming a seventh conductor over the second insulator after the twelfth step by a CVD method;
a fourteenth step of processing the seventh conductor after the thirteenth step to form an eighth conductor;
a fifteenth step of processing the second insulator after the fourteenth step to form a third insulator; and
a sixteenth step of processing the fifth semiconductor after the fifteenth step to form a sixth semiconductor,
wherein exposure to air does not occur between the third step and the fourth step, and
wherein exposure to air does not occur between the eleventh step and the twelfth step.

8. The method for manufacturing the semiconductor device according to claim 7, wherein exposure to air does not occur between the fourth step and the fifth step.

9. The method for manufacturing the semiconductor device according to claim 7, wherein exposure to air does not occur between the fifth step and the sixth step.

10. The method for manufacturing the semiconductor device according to claim 7, wherein heat treatment is performed after the fifth step.

11. The method for manufacturing the semiconductor device according to claim 7, further comprising, before the first step, a step of forming a fourth insulator with a function of blocking hydrogen by a CVD method.

12. The method for manufacturing the semiconductor device according to claim 7, further comprising, after the sixteenth step, a step of forming a fifth insulator with a function of blocking hydrogen by a CVD method.

13. The method for manufacturing the semiconductor device according to claim 7, further comprising, after the fourth step, a step of adding oxygen to the first semiconductor.
